(19) United States
(12) Patent Application Publication
(10) Pub. No.: US 2025/0261527 A1
(43) Pub. Date: Aug. 14, 2025

(54) DISPLAY DEVICE

(71) Applicant: Samsung Display Co., LTD., Yongin-si (KR)

(72) Inventor: Seung Lyong BOK, Yongin-si (KR)

(73) Assignee: Samsung Display Co., LTD., Yongin-si (KR)

(21) Appl. No.: 18/903,634

(22) Filed: Oct. 1, 2024

(30) Foreign Application Priority Data
Feb. 8, 2024 (KR) 10-2024-0019797

(51) Int. Cl. H10K 59/131; H10K 59/35; H10K 59/80

(52) U.S. Cl. CPC H10K 59/131; H10K 59/353; H10K 59/80522

(57) ABSTRACT

A display device including a substrate including light emitting areas, a circuit layer, and an element layer. The circuit layer includes a cathode auxiliary electrode disposed in a portion of a non-light emitting area between the light emitting areas. The element layer includes anode electrodes, a pixel defining layer, first common layers, light emitting layers, a second common layer, and a cathode electrode. A portion of each of a roof portion overlapping a side of the cathode auxiliary electrode and the cathode auxiliary electrode is exposed to the second common layer through a cathode connection hole. In an undercut structure formed by the roof portion, a gap is formed in which the second common layer is separated. The cathode electrode is electrically connected to the cathode auxiliary electrode through the cathode connection hole and the gap in the second common layer.

### CROSS-REFERENCE TO RELATED APPLICATION(S)

This application claims priority to and benefits of Korean Patent Application No. 10-2024-0019797 under 35 U.S.C. § 119, filed on Feb. 8, 2024 in the Korean Intellectual Property Office, the entire contents of which are incorporated herein by reference.

### BACKGROUND

### 1. Technical Field

The disclosure relates to a display device.

### 2. Description of the Related Art

As an information society develops, the demand for a display device for displaying an image is increasing in various forms. For example, the display device has been applied to various electronic devices such as smartphones, digital cameras, laptop computers, navigation devices, and smart televisions.

A display device may be a flat panel display device such as a liquid crystal display device, a field emission display device, or a light emitting display device. Here, the light emitting display device may include an organic light emitting display device including an organic light emitting element, an inorganic light emitting display device including an inorganic light emitting element such as an inorganic semiconductor, and a micro or nano light emitting display device including a micro or nano light emitting element.

The organic light emitting display device displays an image using light emitting elements each including a light emitting layer made of an organic light emitting material. As such, as the organic light emitting display device implements image display using self-light emitting elements, the organic light emitting display device may have relatively superior performance in terms of power consumption, response speed, emission efficiency, luminance, and wide viewing angle compared to other display devices.

A surface of the display device may be a display surface including a display area where an image is displayed. Light emitting areas that emit light with respective luminance and color may be arranged (disposed) in the display area.

### SUMMARY

A display device may include anode electrodes individually disposed in the light emitting areas, first common layers disposed on the anode electrodes, light emitting layers disposed on the first common layers, a second common layer that entirely covers the light emitting layers of the display area, and a cathode electrode disposed on the second common layer.

The cathode electrode may have a wider width than each of the anode electrodes as it is disposed throughout the display area. Accordingly, since it may be difficult to evenly maintain a potential of the cathode electrode throughout the display area, partial luminance differences may occur, which may result in deterioration of image quality.

To prevent such a problem, the display device may further include a cathode auxiliary electrode disposed in some of the non-light emitting areas between the light emitting areas.

However, as the second common layer is disposed between the cathode electrode and the cathode auxiliary electrode, a mask process may be added to partially remove the second common layer for electrical connection between the cathode electrode and the cathode auxiliary electrode. Since a process of manufacturing the display device may become more complicated as the mask process is added, there may be a problem in that it is difficult to reduce the cost and time consumed in manufacturing the display device including the cathode auxiliary electrode.

Aspects of the disclosure provide a display device in which electrical connection between a cathode electrode and a cathode auxiliary electrode may be implemented without separately adding a mask process for a second common layer.

However, aspects of the disclosure are not restricted to those set forth herein. The above and other aspects of the disclosure will become more apparent to one of ordinary skill in the art to which the disclosure pertains by referencing the detailed description of the disclosure given below.

According to an aspect of the disclosure, there is provided a display device that may include a substrate including a display area in which light emitting areas are disposed, a circuit layer disposed on the substrate, and an element layer disposed on the circuit layer. The circuit layer may include a cathode auxiliary electrode disposed in a portion of a non-light emitting area between the light emitting areas in the display area. The element layer may include anode electrodes disposed in the light emitting areas, a pixel defining layer disposed in the non-light emitting area and overlapping an edge of each of the anode electrodes, first common layers disposed on the anode electrodes, light emitting layers disposed on the first common layers, a second common layer disposed on the pixel defining layer and the light emitting layers, and a cathode electrode disposed on the second common layer. A portion of each of a roof portion overlapping a side of the cathode auxiliary electrode and the cathode auxiliary electrode may be exposed to the second common layer through a cathode connection hole. In an undercut structure formed by the roof portion, a gap may be formed in which the second common layer is separated. The cathode electrode may be electrically connected to the cathode auxiliary electrode through the cathode connection hole and the gap in the second common layer.

The light emitting areas may include first light emitting areas emitting light of a first color, second light emitting areas emitting light of a second color having a lower wavelength band than the first color, and third light emitting areas emitting light of a third color having a lower wavelength band than the second color. The first light emitting areas may be parallel to each other in a first direction. The second light emitting areas may be parallel to each other in the first direction. Each of the third light emitting areas may be adjacent to a portion of each of the first light emitting areas and a portion of each of the second light emitting areas in the first direction. In a second direction intersecting the first direction, the first light emitting areas and the second light emitting areas may be alternately disposed. The third light emitting areas may be parallel to each other in the second direction. A first spaced area having a first width may be disposed between two or more third light emitting areas that are parallel in the second direction among the third light emitting areas, and a second spaced area having a second width greater than the first width may be disposed between the two or more third light emitting areas and the other two or more third light emitting areas.

The cathode auxiliary electrode may be disposed in the second spaced area.

In the first direction, a third spaced area may be disposed on a side of the two or more third light emitting areas. The cathode auxiliary electrode may be disposed in the first spaced area and the third spaced area.

The circuit layer may include an interlayer insulating layer disposed on the substrate, a first source drain conductive layer disposed on the interlayer insulating layer, a first planarization layer overlapping the first source drain conductive layer, a second source drain conductive layer disposed on the first planarization layer, and a second planarization layer overlapping the second source drain conductive layer.

The cathode auxiliary electrode may be disposed as the first source drain conductive layer. The roof portion may be disposed as the second source drain conductive layer. The cathode connection hole may include a first hole penetrating through the pixel defining layer and the second planarization layer, and a second hole penetrating through the first planarization layer. A portion of the roof portion may protrude more than the second hole. The gap in the second common layer may be formed in an undercut structure between the roof portion and the second hole.

The substrate may further include a hole area surrounded by the display area, and a hole peripheral area disposed between the hole area and the display area. The circuit layer may further include two or more auxiliary roof portions disposed as the second source drain conductive layer in the hole peripheral area on the first planarization layer and sequentially surrounding the hole area, and one or more separation grooves positioned between the two or more auxiliary roof portions and penetrating through the first planarization layer. A portion of an edge of each of the two or more auxiliary roof portions may protrude more than the one or more separation grooves. A portion of the second common layer disposed in the hole peripheral area may be separated from an undercut structure formed between the two or more auxiliary roof portions and the one or more separation grooves.

The second source drain conductive layer may include a main conductive layer, and a sub-conductive layer disposed on the main conductive layer and including a metal material different from the main conductive layer. The cathode auxiliary electrode may be disposed as the first source drain conductive layer. The roof portion may be disposed as the second source drain conductive layer. The cathode connection hole may include a first hole penetrating through the pixel defining layer and the second planarization layer, and a second hole penetrating through the first planarization layer. A portion of the roof portion exposed through the cathode connection hole may include an undercut structure in which the sub-conductive layer protrudes more than the main conductive layer. The gap in the second common layer may be formed in the undercut structure of a portion of the roof portion.

The substrate may further include a hole area surrounded by the display area, and a hole peripheral area disposed between the hole area and the display area. The circuit layer may further include two or more auxiliary roof portions disposed as the second source drain conductive layer in the hole peripheral area on the first planarization layer and sequentially surrounding the hole area, and one or more separation grooves positioned between the two or more auxiliary roof portions and penetrating through the first planarization layer. A portion of an edge of each of the two or more auxiliary roof portions exposed through the one or more separation grooves may include an undercut structure in which the sub-conductive layer protrudes more than the main conductive layer. A portion of the second common layer disposed in the hole peripheral area may be separated from the undercut structure of the two or more auxiliary roof portions.

The cathode auxiliary electrode may be disposed as the first source drain conductive layer. The roof portion may be disposed on the second planarization layer in the same layer as the anode electrodes. The cathode connection hole may include a first hole penetrating through the pixel defining layer, and a second hole penetrating through the second planarization layer and the first planarization layer. A portion of the roof portion may protrude more than the second hole. The gap in the second common layer may be formed in an undercut structure between the roof portion and the second hole.

The cathode auxiliary electrode may be disposed as the second source drain conductive layer. The roof portion may be disposed on the second planarization layer in the same layer as the anode electrodes. The cathode connection hole may include a first hole penetrating through the pixel defining layer, and a second hole penetrating through the second planarization layer. A portion of the roof portion may protrude more than the second hole. The gap in the second common layer may be formed in an undercut structure between the roof portion and the second hole.

The circuit layer may further include a power auxiliary electrode disposed as the first source drain conductive layer and electrically connected to the cathode auxiliary electrode.

The circuit layer may further include an auxiliary insulating layer disposed on the interlayer insulating layer and overlapping the first source drain conductive layer. Each of the interlayer insulating layer and the auxiliary insulating layer may include an inorganic insulating material. Each of the first planarization layer, the second planarization layer, and the pixel defining layer may include an organic insulating material. The cathode auxiliary electrode may be disposed as the first source drain conductive layer. The cathode connection hole may be connected to an additional connection hole penetrating through the pixel defining layer, the second planarization layer, and the first planarization layer, and may penetrate through the auxiliary insulating layer. The roof portion may be a portion of the first planarization layer disposed around the additional connection hole and protruding more than the auxiliary insulating layer. The gap in the second common layer may be formed in an undercut structure between the roof portion and the auxiliary insulating layer.

According to an aspect of the disclosure, there is provided a display device that may include a substrate including a display area in which light emitting areas are disposed, a circuit layer disposed on the substrate, and an element layer disposed on the circuit layer. The circuit layer may include an interlayer insulating layer disposed on the substrate, a first source drain conductive layer disposed on the interlayer insulating layer, a first planarization layer overlapping the first source drain conductive layer, a second source drain conductive layer disposed on the first planarization layer, a second planarization layer overlapping the second source drain conductive layer, and a cathode auxiliary electrode disposed as one of the first source drain conductive layer and the second source drain conductive layer in a portion of a non-light emitting area between the light emitting areas of the display area. The element layer may include anode electrodes disposed in the light emitting areas, a pixel definition layer disposed in the non-light emitting area and overlapping an edge of each of the anode electrodes, first common layers disposed on the anode electrodes, light emitting layers disposed on the first common layers, a second common layer disposed on the pixel defining layer and the light emitting layers, and a cathode electrode disposed on the second common layer. A portion of each of a roof portion overlapping a side of the cathode auxiliary electrode and the cathode auxiliary electrode may be exposed to the second common layer through a cathode connection hole. In an undercut structure formed by the roof portion, a gap may be formed in which the second common layer is separated. The cathode electrode may be electrically connected to the cathode auxiliary electrode through the cathode connection hole and the gap of the second common layer.

The cathode auxiliary electrode may be disposed as the first source drain conductive layer. The roof portion may be disposed as the second source drain conductive layer. The cathode connection hole may include a first hole penetrating through the pixel defining layer and the second planarization layer, and a second hole penetrating through the first planarization layer. A portion of the roof portion may protrude more than the second hole. The gap in the second common layer may be formed in an undercut structure between the roof portion and the second hole.

The substrate may further include a hole area surrounded by the display area, and a hole peripheral area disposed between the hole area and the display area. The circuit layer may further include two or more auxiliary roof portions disposed as the second source drain conductive layer in the hole peripheral area on the first planarization layer and sequentially surrounding the hole area, and one or more separation grooves positioned between the two or more auxiliary roof portions and penetrating through the first planarization layer. A portion of an edge of each of the two or more auxiliary roof portions may protrude more than the one or more separation grooves. A portion of the second common layer disposed in the hole peripheral area may be separated from an undercut structure formed between the two or more auxiliary roof portions and the one or more separation grooves.

The second source drain conductive layer may include a main conductive layer, and a sub-conductive layer disposed on the main conductive layer and including a metal material different from the main conductive layer. The cathode auxiliary electrode may be disposed as the first source drain conductive layer. The roof portion may be disposed as the second source drain conductive layer. The cathode connection hole may include a first hole penetrating through the pixel defining layer and the second planarization layer, and a second hole penetrating through the first planarization layer. A portion of the roof portion exposed through the cathode connection hole may include an undercut structure in which the sub-conductive layer protrudes more than the main conductive layer. The gap in the second common layer may be formed in the undercut structure of a portion of the roof portion.

The substrate may further include a hole area surrounded by the display area, and a hole peripheral area disposed between the hole area and the display area. The circuit layer may further include two or more auxiliary roof portions disposed as the second source drain conductive layer in the hole peripheral area on the first planarization layer and sequentially surrounding the hole area, and one or more separation grooves positioned between the two or more auxiliary roof portions and penetrating through the first planarization layer. A portion of an edge of each of the two or more auxiliary roof portions exposed through the one or more separation grooves may include an undercut structure in which the sub-conductive layer protrudes more than the main conductive layer. A portion of the second common layer disposed in the hole peripheral area may be separated from the undercut structure of the two or more auxiliary roof portions.

The light emitting areas may include first light emitting areas emitting light of a first color, second light emitting areas emitting light of a second color having a lower wavelength band than the first color, and third light emitting areas emitting light of a third color having a lower wavelength band than the second color. The first light emitting areas may be parallel to each other in a first direction. The second light emitting areas may be parallel to each other in the first direction. Each of the third light emitting areas may be adjacent to a portion of each of the first light emitting areas and a portion of each of the second light emitting areas in the first direction. In a second direction intersecting the first direction, the first light emitting areas and the second light emitting areas may be alternately disposed. The third light emitting areas may be parallel to each other in the second direction. A first spaced area having a first width may be disposed between two or more third light emitting areas that are parallel in the second direction among the third light emitting areas, and a second spaced area having a second width greater than the first width may be disposed between the two or more third light emitting areas and the other two or more third light emitting areas. The cathode auxiliary electrode may be disposed in the second spaced area.

In the first direction, a third spaced area may be disposed on a side of the two or more third light emitting areas. The cathode auxiliary electrode may be further disposed in the third spaced area.

The display device according to embodiments may include a substrate, a circuit layer disposed on the substrate and including a cathode auxiliary electrode, and an element layer disposed on the circuit layer and including anode electrodes, first common layers, light emitting layers, a second common layer, and a cathode electrode.

According to embodiments, a portion of each of the roof portion overlapping a side of the cathode auxiliary electrode and cathode auxiliary electrode may be exposed by a cathode connection hole, and in an undercut structure formed by the roof portion, a gap may be formed in which the second common layer is separated. The cathode electrode may be electrically connected to the cathode auxiliary electrode through the gap between the cathode connection hole and the second common layer.

According to embodiments, electrical connection between the cathode electrode and the cathode auxiliary electrode may be implemented through the undercut structure provided by the roof portion without adding the mask process of partially removing the second common layer. Therefore, the cost and time required to manufacture the display device including the cathode auxiliary electrode may be reduced.

However, effects according to the embodiments of the disclosure are not limited to those examples above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view illustrating a display device according to embodiments;

FIG. 2 is a schematic plan view illustrating the display device of FIG. 1;

FIG. 3 is a schematic cross-sectional view taken along line A-A′ of FIG. 2;

FIG. 4 is a schematic plan view illustrating portion B of FIG. 2;

FIG. 5 is a schematic diagram of an equivalent circuit illustrating a light emitting pixel driver of FIG. 4;

FIG. 6 is a schematic cross-sectional view illustrating a first transistor, a second transistor, a fourth transistor, and a sixth transistor and a light emitting element of FIG. 5;

FIG. 7 is a schematic plan view illustrating a cathode auxiliary electrode in portion B of FIG. 2 according to embodiments;

FIG. 8 is a schematic cross-sectional view taken along line C-C′ of FIG. 7 according to an embodiment;

FIG. 9 is a schematic plan view illustrating a display device according to other embodiments;

FIG. 10 is a schematic cross-sectional view taken along line D-D′ of FIG. 9;

FIG. 11 is a schematic plan view illustrating portion E of FIG. 9.

FIG. 12 is a schematic cross-sectional view taken along line F-F′ of FIG. 11 according to an embodiment of FIG. 8;

FIG. 13 is an enlarged schematic view illustrating portion G of FIG. 12;

FIG. 14 is a schematic cross-sectional view taken along line C-C′ of FIG. 7 according to an embodiment;

FIG. 15 is a schematic cross-sectional view taken along line F-F′ of FIG. 11 according to an embodiment of FIG. 14;

FIG. 16 is an enlarged schematic view illustrating portion H of FIG. 15;

FIGS. 17, 18, 19, and 20 are each schematic cross-sectional views taken along line C-C′ of FIG. 7 according to an embodiment; and

FIG. 21 is a schematic plan view illustrating a cathode auxiliary electrode in portion B of FIG. 2 according to an embodiment.

### DETAILED DESCRIPTION OF THE EMBODIMENTS

Embodiments of the disclosure will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts that are not associated with the description may not be provided in order to more clearly describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and/or vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the spirit and scope of the disclosure herein.

The terms “about,” “approximately,” and “substantially” as used herein are inclusive of the stated value and mean within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within +30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

As used herein, the singular forms, “a,” “an,” and “the” are intended to include the plural forms as well, unless the context clearly indicates otherwise.

Unless otherwise defined or implied, all terms used herein (including technical and scientific terms) have the same meaning as commonly understood by those skilled in the art to which the disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

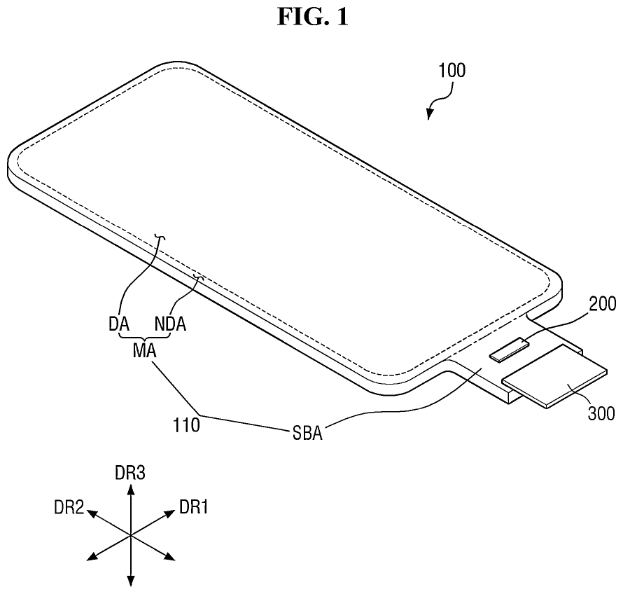

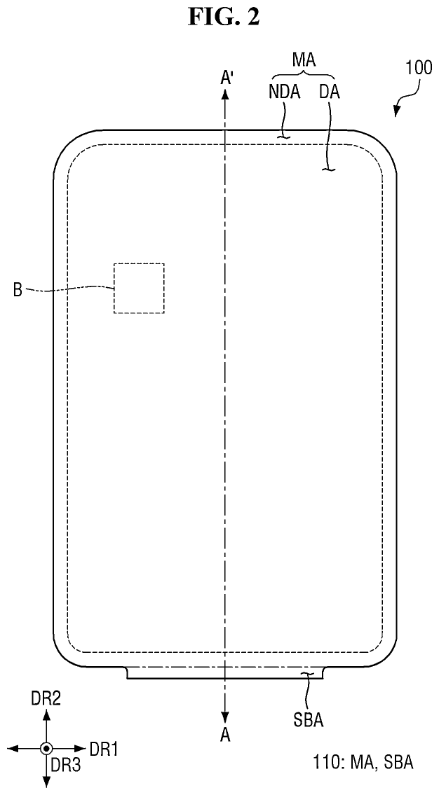

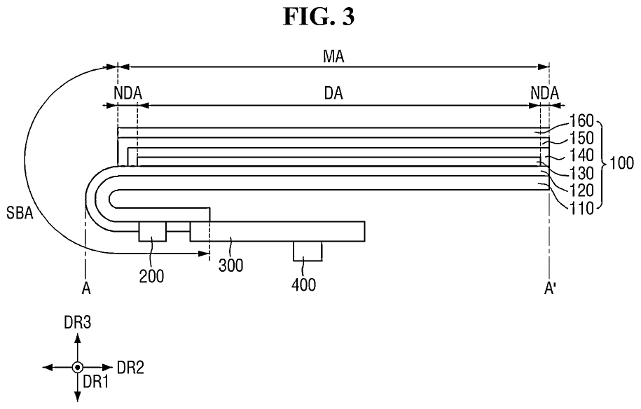

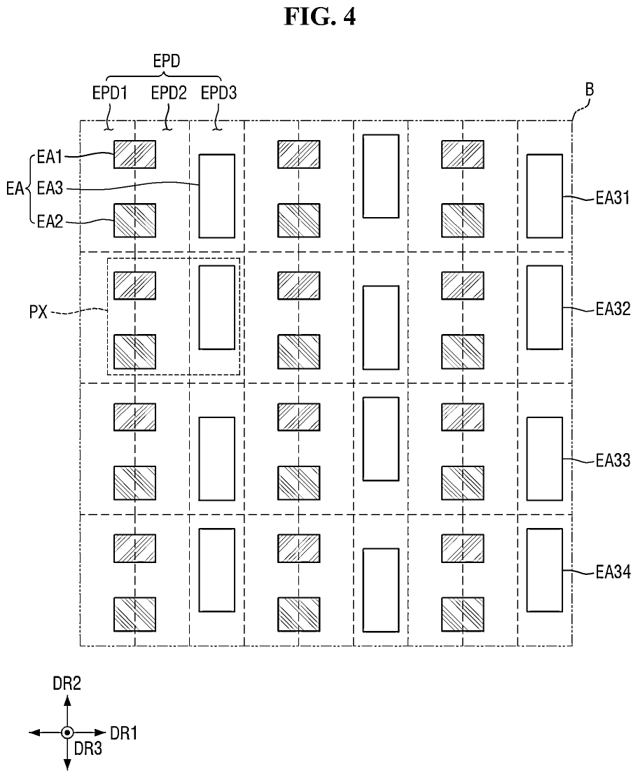

FIG. 1 is a schematic perspective view illustrating a display device according to embodiments. FIG. 2 is a schematic plan view illustrating the display device of FIG. 1. FIG. 3 is a schematic cross-sectional view taken along line A-A′ of FIG. 2. FIG. 4 is a schematic plan view illustrating portion B of FIG. 2.

Referring to FIGS. 1 and 2, a display device 100 is a device that displays a moving image or a still image, and may be used as a display screen of each of various products such as a television, a laptop computer, a monitor, a billboard, and an Internet of Things (IoT) device as well as portable electronic devices such as a mobile phone, a smartphone, a tablet personal computer (PC), a smartwatch, a watch phone, a mobile communication terminal, an electronic organizer, an electronic book, a portable multimedia player (PMP), a navigation device, or an ultra mobile PC (UMPC).

The display device 100 may be a light emitting display device such as an organic light emitting display device using an organic light emitting diode, a quantum dot light emitting display device including a quantum dot light emitting layer, an inorganic light emitting display device including an inorganic semiconductor, or a micro light emitting display device using a micro or nano light emitting diode (micro or nano LED). Hereinafter, the description will be made mainly based on the fact that the display device 100 is an organic light emitting display device. However, the disclosure is not limited thereto and may be applied to display devices including organic insulating materials, organic light emitting materials, and metal materials.

The display device 100 may be formed to be flat, but is not limited thereto. For example, the display device 100 may include curved surface portions formed at left and right distal ends thereof and having a constant curvature or a variable curvature. The display device 100 may be flexibly formed to be curved, bent, folded, or rolled.

As illustrated in FIGS. 1, 2, and 3, the display device 100 may include a substrate 110.

The substrate 110 may include a main area MA corresponding to a display surface of the display device 100 and a sub-area SBA protruding from a side of the main area MA.

As illustrated in FIG. 2, the main area MA may include a display area DA disposed at most of the center and a non-display area NDA disposed around the display area DA.

The display area DA may be formed in a rectangular plane having short sides extending in a first direction DR1 and long sides extending in a second direction DR2 intersecting the first direction DR1. A corner where the short side in the first direction DR1 and the long side in the second direction DR2 meet may be rounded to have a predetermined or selected curvature or may be formed at a right angle. The planar shape of the display area DA is not limited to the quadrangular shape, and the display area DA may be formed in other polygonal, circular, or oval shapes.

The non-display area NDA may be disposed at an edge of the main area MA to surround the display area DA.

The sub-area SBA may be an area protruding from the non-display area NDA of the main area MA to a side in the second direction DR2.

FIGS. 2 and 3 illustrate the display device 100 with a portion of the sub-area SBA curved.

As illustrated in FIGS. 2 and 3, as a portion of the sub-area SBA is deformed into a curved shape, another portion of the sub-area SBA may be disposed on a rear surface of the substrate 110 opposite to the display surface.

Referring to FIG. 3, the display device 100 according to embodiments may include a substrate 110, a circuit layer 120 disposed on the substrate 110, and an element layer 130 disposed on the circuit layer 120.

The display device 100 according to embodiments may further include a sealing layer 140 disposed on the element layer 130, and a touch sensor layer 150 disposed on the sealing layer 140.

The display device 100 according to embodiments may further include a polarizing layer 160 disposed on the touch sensor layer 150 to reduce reflection of external light.

The display device 100 according to embodiments may further include a cover window disposed on the polarizing layer 160 and a bracket disposed below the rear surface of the substrate 110. The cover window may face the substrate 110 and may be attached to the polarizing layer 160 or bound to the bracket by a transparent adhesive member such as an optically clear adhesive (OCA) film or an optically clear resin (OCR). The bracket may accommodate the substrate 110 and a circuit board 300.

The cover window may also be made of an inorganic material such as glass or also be made of an organic material such as plastic or a polymer material. The cover window may protect the touch sensor layer 150, the sealing layer 140, the element layer 130, and the circuit layer 120 from electrical and physical shock on the display surface.

The substrate 110 may be made of an insulating material such as a polymer resin. For example, the substrate 110 may be made of polyimide. The substrate 110 may be a flexible substrate that may be bent, folded, and rolled.

In other embodiments, the substrate 110 may be made of an insulating material such as glass.

The circuit layer 120 may include conductive layers, one or more semiconductor layers, and insulating layers interposed between the conductive layers and/or the one or more semiconductor layers. The circuit layer 120 may include transistors provided with one or more semiconductor layers and one or more conductive layers, and signal lines each provided with at least one of the conductive layers.

The element layer 130 may include light emitting elements that emit light according to a driving current applied from the circuit layer 120.

The sealing layer 140 may cover the circuit layer 120 and the element layer 130 and may block permeation of oxygen or moisture into the element layer 130.

The touch sensor layer 150 may be disposed in the main area MA on the sealing layer 140. The touch sensor layer 150 may include touch electrodes for sensing a touch of a person or object.

The polarizing layer 160 may prevent image visibility from being reduced due to reflection of external light by blocking external light reflected from the touch sensor layer 150, the sealing layer 140, the element layer 130, and the circuit layer 120 and interfaces between the touch sensor layer 150, the sealing layer 140, the element layer 130, and/or the circuit layer 120.

The display driving circuit 200 may be provided as an integrated circuit (IC) chip.

The display driving circuit 200 may be mounted on the sub-area SBA of the substrate 110 in a chip on glass (COG) manner, a chip on plastic (COP) manner, or an ultrasonic bonding manner, but is not limited thereto.

For example, the display driving circuit 200 may be attached onto the circuit board 300 in a chip on film (COF) manner.

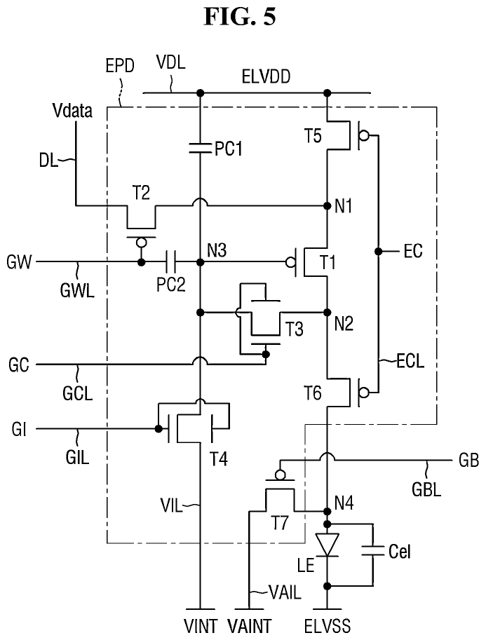

The display driving circuit 200 may supply data signals to data lines (DL in FIG. 5) of the circuit layer (120 in FIG. 3).

The circuit board 300 may be a flexible film such as a flexible printed circuit board, a printed circuit board, or a chip on film.

The circuit board 300 may be bonded to signal pads disposed at an edge of the sub-area SBA of the substrate 110 using a low-resistance, high-reliability material such as an anisotropic conductive film or SAP, and may be electrically connected to the circuit layer 120.

The display device 100 may further include a touch driving circuit 400 for driving the touch sensor layer 150.

The touch driving circuit 400 may be provided as an integrated circuit (IC) chip and mounted on the circuit board 300.

The touch driving circuit 400 may apply a touch driving signal to driving electrodes provided in the touch sensor layer 150, may receive a touch sensing signal from touch nodes through sensing electrodes, and may sense a change amount in charge of mutual capacitance based on the touch sensing signal.

The touch driving circuit 400 may determine whether or not a user has performed a touch, whether or not the user has approached the display device and the like, according to the touch sensing signal of the touch nodes. The touch of the user refers to when an object such as the user's finger or pen is in direct contact with a front surface of the display device 100. The approaching of the user refers to when the user's finger or the object such as the pen is positioned apart from the front surface of the display device 100, such as hovering.

The substrate 110 may include a main area MA and a sub-area SBA. The main area MA may include a display area DA and a non-display area NDA.

Referring to FIG. 4, the display area DA of the substrate 110 of the display device 100 according to embodiments may include light emitting areas EA. The display area DA may further include a non-light emitting area disposed between the light emitting areas EA.

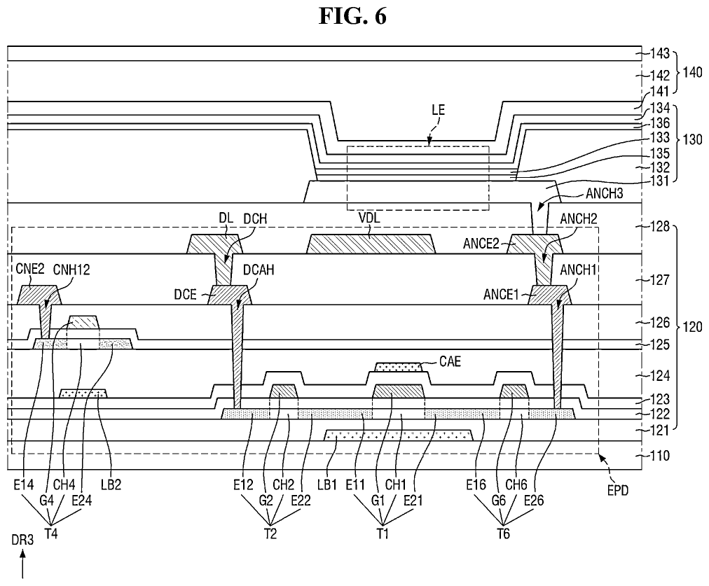

The element layer (130 in FIG. 3) may include light emitting elements (LE in FIGS. 5 and 6) each disposed in the light emitting areas EA.

The circuit layer (120 in FIG. 3) may include light emitting pixel drivers EPD arranged to be parallel to each other in the first direction DR1 and the second direction DR2 in the display area DA. The light emitting pixel drivers EPD may be electrically connected to the light emitting element (LE in FIGS. 5 and 6) of the element layer 130, respectively.

The light emitting areas EA may have a rectangular planar shape or a rhombic planar shape. However, this is only an example, and the planar shape of the light emitting areas EA according to embodiments is not limited to that illustrated in FIG. 4. For example, the light emitting areas EA may have a polygonal planar shape such as a square, pentagon, or hexagon, or a circular or oval planar shape including curved edges.

The light emitting areas EA may include first light emitting areas EA1 that emit light of a first color in a predetermined or selected wavelength band, second light emitting areas EA2 that emit light of a second color in a wavelength band lower than that of the first color, and third light emitting areas EA3 that emit light of a third color in a wavelength band lower than that of the second color.

As an example, the first color may be red in a wavelength band of approximately 600 nm to approximately 750 nm. The second color may be green in a wavelength band of approximately 480 nm to approximately 560 nm. The third color may be blue in a wavelength band of approximately 370 nm to approximately 460 nm.

The first light emitting areas EA1 may be arranged to be parallel to each other in the first direction DR1.

The second light emitting areas EA2 may be arranged to be parallel to each other in the first direction DR1.

Each of the third light emitting areas EA3 may be adjacent to a portion of each of the first light emitting areas EA1 and a portion of each of the second light emitting areas EA2 in the first direction DR1.

In the second direction DR2, the first light emitting areas EA1 and the second light emitting areas EA2 may be arranged to alternate with and to be parallel to each other.

In the second direction DR2, the third light emitting areas EA3 may be arranged to be parallel to each other.

Among the first light emitting areas EA1, the second light emitting areas EA2, and the third light emitting areas EA3, the third light emitting areas EA3 may be disposed with the largest area, and the first light emitting areas EA1 may be disposed with the smallest area.

As an example, the first light emitting areas EA1, the second light emitting areas EA2, and the third light emitting areas EA3 may have the same or similar width in the first direction DR1, and among the first light emitting areas EA1, the second light emitting areas EA2, and the third light emitting areas EA3, the third light emitting areas EA3 may have the largest width in the second direction DR2, and the first light emitting areas EA1 may have the smallest width in the second direction DR2.

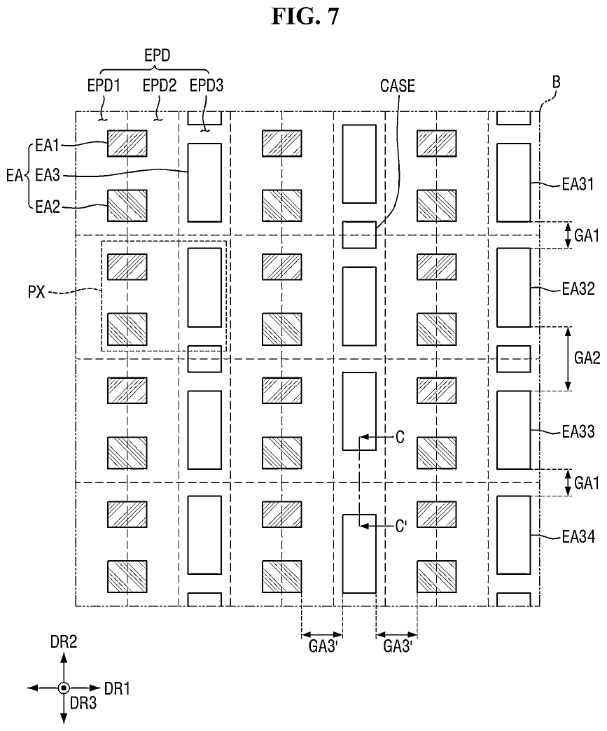

A first spaced area (GA1 in FIG. 7) having a first width may be disposed between two or more third light emitting areas EA3 that are parallel in the second direction DR2 among the third light emitting areas EA3, and a second spaced area (GA2 in FIG. 7) having a second width greater than the first width may be disposed between the two or more third light emitting areas EA3 and the other two or more third light emitting areas EA3.

The first spaced area (GA1 in FIG. 7) and the second spaced area (GA2 in FIG. 7) may be alternately disposed in the first direction DR1.

In this way, as the light emitting areas EA include the first light emitting areas EA1, the second light emitting areas EA2, and the third light emitting areas EA3, the light emitting pixel drivers EPD may include first light emitting pixel drivers EPD1 electrically connected to the light emitting elements LE of the first light emitting areas EA1, second light emitting pixel drivers EPD2 electrically connected to the light emitting elements LE of the second light emitting areas EA2, and third light emitting pixel drivers EPD3 electrically connected to the light emitting elements LE of the third light emitting areas EA3.

Pixels PX that display each luminance and color may be provided by the first light emitting area EA1, the second light emitting area EA2, and the third light emitting area EA3 adjacent to each other among the light emitting areas EA.

In other words, the pixels PX may be basic units that display various colors, including white, at predetermined or selected luminance.

Each of the pixels PX may include at least one first light emitting area EA1, at least one second light emitting area EA2, and at least one third light emitting area EA3 adjacent to each other. Accordingly, each of the pixels PX may display various colors through mixing of light emitted from the first, second, and third light emitting areas EA1, EA2, and EA3 adjacent to each other.

FIG. 5 is a schematic diagram of an equivalent circuit illustrating a light emitting pixel driver of FIG. 4. Referring to FIG. 5, one of the light emitting elements LE of the element layer 130 may be electrically connected between one of the light emitting pixel drivers EPD of the circuit layer 120 and a second power ELVSS.

For example, an anode electrode of the light emitting element LE may be electrically connected to the light emitting pixel driver EPD, and the second power ELVSS having a lower voltage level than a first power ELVDD may be applied to a cathode electrode of the light emitting element LE.

A capacitor Cel may be connected in parallel with the light emitting element LE and represent parasitic capacitance between the anode electrode and the cathode electrode.

The circuit layer 120 may include a data line DL that transmits a data signal Vdata, a first power line VDL that transmits the first power ELVDD, a first initialization voltage line VIL that transmits a first initialization voltage VINT, and a second initialization voltage line VAIL that transmits a second initialization voltage VAINT.

The circuit layer 120 may further include a scan write line GWL that transmits a scan write signal GW, a scan initialization line GIL that transmits a scan initialization signal GI, an emission control line ECL that transmits an emission control signal EC, and a bias control line GBL that transmits a bias control signal GB.

One light emitting pixel driver EPD of the circuit layer 120 may include a first transistor T1 that generates a driving current for driving the light emitting element LE, two or more transistors T2 to T7 electrically connected to the first transistor T1 or the light emitting element LE, and at least one capacitor PC1, PC2.

The first transistor T1 may be disposed between a first node N1 and a second node N2. The first node N1 may be electrically connected to a first electrode (e.g., a source electrode) of the first transistor T1. The second node N2 may be electrically connected to a second electrode (e.g., a drain electrode) of the first transistor T1.

The first pixel capacitor PC1 may be connected between the first power line VDL and a third node N3. The third node N3 may be electrically connected to a gate electrode of the first transistor T1.

For example, the gate electrode of the first transistor T1 may be electrically connected to the first power line VDL through the first pixel capacitor PC1.

Accordingly, a potential of the gate electrode of the first transistor T1 may be maintained at a voltage charged in the first power line VDL.

The second transistor T2 may be electrically connected between the data line DL and the first node N1.

In other words, the second transistor T2 may be electrically connected between the first electrode of the first transistor T1 and the data line DL.

The second transistor T2 may be turned on by the scan write signal GW of the scan write line GWL. The second pixel capacitor PC2 may be connected between the second transistor T2 and the third node N3.

For example, the first electrode of the first transistor T1 may be electrically connected to the data line DL through the second transistor T2.

The third transistor T3 may be disposed between the second node N2 and the third node N3. For example, the third transistor T3 may be electrically connected between the gate electrode of the first transistor T1 and the second electrode of the first transistor T1. The third transistor T3 may be turned on by the gate control signal GC of the gate control line GCL.

A voltage difference between the second node N2 and the third node N3 may be initialized through the turned-on third transistor T3.

The fourth transistor T4 may be electrically connected between the first initialization voltage line VIL and the third node N3. For example, the fourth transistor T4 may be connected between the gate electrode of the first transistor T1 and the first initialization voltage line VIL. The fourth transistor T4 may be turned on by the scan initialization signal GI of the scan initialization line GIL.

A potential of the third node N3 may be initialized through the turned-on fourth transistor T4.

The fifth transistor T5 may be electrically connected between the first node N1 and the first voltage line VDL.

The sixth transistor T6 may be electrically connected between the second node N2 and a fourth node N4. The fourth node N4 may be electrically connected to the anode electrode of the light emitting element LE.

For example, the fifth transistor T5 may be electrically connected between the first electrode of the first transistor T1 and the first power line VDL.

The sixth transistor T6 may be electrically connected between the second electrode of the first transistor T1 and the anode electrode of the light emitting element LE.

In other words, the first electrode (e.g., the source electrode) of the first transistor T1 may be electrically connected to the first power line VDL through the fifth transistor T5. The second electrode (e.g., the drain electrode) of the first transistor T1 may be electrically connected to the anode electrode of the light emitting element LE through the sixth transistor T6.

The fifth transistor T5 and the sixth transistor T6 may be turned on by the emission control signal EC of the emission control line ECL.

In case that the data signal Vdata of the data line DL is transmitted to the first electrode of the first transistor T1 through the turned-on second transistor T2, a voltage difference between the gate electrode of the first transistor T1 and the first electrode of the first transistor T1 may be a difference voltage between the first power ELVDD and the data signal Vdata.

In case that the voltage difference between the gate electrode of the first transistor T1 and the first electrode of the first transistor T1, that is, a gate-source voltage difference is a threshold voltage or more, the first transistor T1 may be turned on, thereby generating a drain-source current of the first transistor T1 corresponding to the data signal Vdata.

Subsequently, in case that the fifth transistor T5 and the sixth transistor T6 are turned on, the first transistor T1 may be connected in series with the light emitting element LE between the first power line VDL and a second power line VSL. Accordingly, the drain-source current of the first transistor T1 corresponding to the data signal Vdata may be supplied as a driving current of the light emitting element LE.

Accordingly, the light emitting element LE may emit light with luminance corresponding to the data signal Vdata.

The seventh transistor T7 may be electrically connected between the fourth node N4 and the second initialization voltage line VAIL. The seventh transistor T7 may be electrically connected between the anode electrode of the light emitting element LE and the second initialization voltage line VAIL. The seventh transistor T7 may be turned on by the bias control signal GB of the bias control line GBL.

A potential of the fourth node N4 may be initialized through the turned-on seventh transistor T7.

According to embodiments, among the first to seventh transistors T1 to T7, the third transistor T3 and the fourth transistor T4 may be N-type MOSFETs, and the remaining transistors T1, T2, and T5 to T7 except for the third transistor T3 and the fourth transistor T4 may be P-type MOSFETs.

For example, among the first to seventh transistors T1 to T7 included in the light emitting pixel driver EPD, the third transistor T3 and the fourth transistor T4 may be provided as N-type MOSFETs, while the remaining transistors T1, T2, and T5 to T7 except for the third transistor T3 and the fourth transistor T4 may be provided as P-type MOSFETs.

Accordingly, according to embodiments, the circuit layer 120 may include a first semiconductor layer (CH1, E11, E21, CH2, E12, E22, CH6, E16, and E26 in FIG. 6) and a second semiconductor layer (CH4, E14, and E24 in FIG. 7).

The first semiconductor layer may include a channel portion, a first electrode portion, and a second electrode of each of the P-type MOSFETs of the first to seventh transistors T1 to T7 of each of the light emitting pixel drivers EPD, that is, the first transistor T1, the second transistor T2, the fifth transistor T5, the sixth transistor T6, and the seventh transistor T7. In each of the first transistor T1, the second transistor T2, the fifth transistor T5, the sixth transistor T6, and the seventh transistor T7, the channel portion may overlap the gate electrode. In each of the first transistor T1, the second transistor T2, the fifth transistor T5, the sixth transistor T6, and the seventh transistor T7, the first electrode portion and the second electrode portion may be connected to both ends of the channel portion. The first electrode portion may be the first electrode of the transistor, and the second electrode portion may be the second electrode of the transistor.

The second semiconductor layer may include a channel portion, a first electrode portion, and a second electrode portion of each of the N-type MOSFETs of the first to seventh transistors T1 to T7 of each of the light emitting pixel drivers EPD, that is, the third transistor T3 and the fourth transistor T4. In the third transistor T3 and the fourth transistor T4, the channel portion may be disposed between the first and second gate electrodes that overlap each other, and may overlap the first gate electrode and the second gate electrode. In each of the third transistor T3 and the fourth transistor T4, the first electrode portion and the second electrode portion may be connected to both ends of the channel portion. The first electrode portion may be the first electrode, and the second electrode portion may be the second electrode.

FIG. 6 is a schematic cross-sectional view illustrating a first transistor, a second transistor, a fourth transistor, and a sixth transistor and a light emitting element of FIG. 5.

Referring to FIG. 6, the display device 100 according to embodiments may include a substrate 110, a circuit layer 120 on the substrate 110, and an element layer 130 on the circuit layer 120.

The display device 100 may further include a sealing layer 140 on the element layer 130.

According to embodiments, the circuit layer 120 may include an interlayer insulating layer 126 disposed on the substrate 110, first source drain conductive layers ANCE1, VIL, and DCE disposed on the interlayer insulating layer 126, a first planarization layer 127 covering the first source drain conductive layers, second source drain conductive layer DL and ANCE2 disposed on the first planarization layer 127, and a second planarization layer 128 covering the second source drain conductive layers.

According to embodiments, the circuit layer 120 may further include first semiconductor layer CH1, E11, E21, CH2, E12, E22, CH6, E16, and E26 disposed on the substrate 110, a first gate insulating layer 122 covering the first semiconductor layers, first gate conductive layers G1, G2, and G6 disposed on the first gate insulating layer 122, a second gate insulating layer 123 covering the first gate conductive layers, second gate conductive layers CAE and LB2 disposed on the second gate insulating layer 123, an additional interlayer insulating layer 124 covering the second gate conductive layers, second semiconductor layer CH4, E14, and E24 disposed on the additional interlayer insulating layer 124, a third gate insulating layer 125 covering the second semiconductor layers, and a third gate conductive layer G4 disposed on the third gate insulating layer 125. In this case, the interlayer insulating layer 126 may cover the third gate conductive layer G4 on the third gate insulating layer 125.

According to embodiments, the circuit layer 120 may further include a buffer layer 121 covering the substrate 110. In this case, the first semiconductor layer may be disposed on the buffer layer 121. The buffer layer 121 may cover a first light blocking portion LB1 on the substrate 110.

The first light blocking portion LB1 may overlap the channel portion CH1 of the first transistor T1.

As described above with referent to FIG. 5, the circuit layer 120 may include the light emitting pixel drivers EPD each electrically connected to the light emitting elements LE disposed in the light emitting areas EA, and the lines that transmit various signals and voltages to the light emitting pixel drivers EPD.

The light emitting pixel drivers EPD may include a first transistor T1 and two or more transistors T2 to T7 electrically connected to the first transistor T1 or the light emitting element LE.

As illustrated in FIG. 6, according to embodiments, the first transistor T1 may include a channel portion CH1, a first electrode portion E11, and a second electrode portion E21 disposed on the first semiconductor layer on the substrate 110, and a gate electrode G1 disposed on the first gate conductive layer on the first gate insulating layer 122.

The first electrode portion E11 may be connected to a side of the channel portion CH1, and the second electrode portion E21 may be connected to another side of the channel portion CH1.

The first electrode portion E11 and the second electrode portion E21 may be doped at a higher concentration than the channel portion CH1.

The gate electrode G1 may overlap the channel portion CH1.

Likewise, the second transistor T2 may include a channel portion CH2, a first electrode portion E12, and a second electrode portion E22 disposed on the first semiconductor layer on the substrate 110, and a gate electrode G2 disposed on the first gate conductive layer on the first gate insulating layer 122 and overlapping the channel portion CH2.

The sixth transistor T6 may include a channel portion CH6, a first electrode portion E16, and a second electrode portion E26 disposed on the first semiconductor layer on the substrate 110, and a gate electrode G6 disposed on the first gate conductive layer on the first gate insulating layer 122 and overlapping the channel portion CH6.

The first electrode portion E12 of the second transistor T2 may be electrically connected to the data line DL through a data connection electrode DCE.

The data connection electrode DCE may be disposed on the first source drain conductive layer on the interlayer insulating layer 126, and may be electrically connected to the first electrode portion E12 of the second transistor T2 through a data auxiliary connection hole DCAH. The data auxiliary connection hole DCAH may penetrate through the interlayer insulating layer 126, the third gate insulating layer 125, the additional interlayer insulating layer 124, the second gate insulating layer 123, and the first gate insulating layer 122.

The data line DL may be disposed on the second source drain conductive layer on the first planarization layer 127, and may be electrically connected to the data connection electrode DCE through a data connection hole DCH penetrating through the first planarization layer 127.

The second electrode portion E22 of the second transistor T2 may be connected to the first electrode portion E11 of the first transistor T1.

The second electrode portion E21 of the first transistor T1 may be connected to the first electrode portion E16 of the sixth transistor T6.

The second electrode portion E26 of the sixth transistor T6 may be electrically connected to the anode electrode 131 through a first anode connection electrode ANCE1 and a second anode connection electrode ANCE2.

The first anode connection electrode ANCE1 may be disposed on the first source drain conductive layer on the interlayer insulating layer 126, and may be electrically connected to the second electrode portion E26 of the sixth transistor T6 through a first anode contact hole ANCH1.

The first anode contact hole ANCH1 may penetrate through the interlayer insulating layer 126, the third gate insulating layer 125, the additional interlayer insulating layer 124, the second gate insulating layer 123, and the first gate insulating layer 122.

The second anode connection electrode ANCE2 may be disposed on the second source drain conductive layer on the first planarization layer 127, and may be electrically connected to the first anode connection electrode ANCE1 through a second anode contact hole ANCH2 penetrating through the first planarization layer 127.

The anode electrode 131 may be disposed on the second planarization layer 128, and may be electrically connected to the second anode connection electrode ANCE2 through a third anode contact hole ANCH3 penetrating through the second planarization layer 128.

According to embodiments, since the fifth transistor (T5 in FIG. 5) and the seventh transistor (T7 in FIG. 5) may have substantially the same structure as the first transistor T1, the second transistor T2, and the sixth transistor T6, redundant descriptions will be omitted below.

The first gate conductive layer on the first gate insulating layer 122 may include a gate electrode of each of the first transistor T1, the second transistor T2, the fifth transistor T5, the sixth transistor T6, and the seventh transistor T7.

The first gate conductive layer on the first gate insulating layer 122 may further include a scan write line GWL electrically connected to the gate electrode G2 of the second transistor T2, and a bias control line GBL electrically connected to the gate electrode of the seventh transistor T7.

The first gate conductive layer may further include a scan initialization line GIL extending in the first direction DR1.

The first gate conductive layer may further include an emission control line ECL electrically connected to the gate electrode of the fifth transistor T5 and the gate electrode of the sixth transistor T6.

According to embodiments, the circuit layer 120 may further include a capacitor electrode CAE that overlaps the gate electrode G1 of the first transistor T1.

The capacitor electrode CAE may be disposed on the second gate conductive layer on the second gate insulating layer 123.

The capacitor electrode CAE may be electrically connected to the first power line (VDL in FIG. 5). As an example, the first power line VDL may be disposed on the second gate conductive layer on the second gate insulating layer 123, and the capacitor electrode CAE may be provided as a portion of the first power line VDL.

The first pixel capacitor PC1 may be provided between the gate electrode G1 of the first transistor T1 and the first power line (VDL in FIG. 5) by an overlapping area between the gate electrode G1 of the first transistor T1 and the capacitor electrode CAE.

According to embodiments, unlike the first transistor T1, the second transistor T2, and the sixth transistor T6 being a P-type MOSFET, the fourth transistor T4 may be an N-type MOSFET.

Accordingly, the fourth transistor T4 may include a channel portion CH4, a first electrode portion E14, and a second electrode portion E24 disposed on the second semiconductor layer on the additional interlayer insulating layer 124, and a gate electrode G4 disposed on the third gate conductive layer on the third gate insulating layer 125 and overlapping the channel portion CH4.

The fourth transistor T4 may further include a second light blocking portion LB2 disposed below the channel portion CH4 and overlapping the channel portion CH4.

The second light blocking portion LB2 may be a bottom gate electrode electrically connected to the gate electrode G4.

As an example, the second light blocking portion LB2 may be a portion of the scan initialization line GIL.

The scan initialization line GIL may be disposed on the second gate conductive layer on the second gate insulating layer 123.

According to embodiments, since the third transistor T3 may have substantially the same structure as the fourth transistor T4, redundant descriptions will be omitted below.

The first electrode portion E14 of the fourth transistor T4 may be electrically connected to the first initialization voltage line (VIL in FIG. 5) through a second connection electrode CNE2.

The second connection electrode CNE2 may be disposed on the first source drain conductive layer on the interlayer insulating layer 126.

The second connection electrode CNE2 may be electrically connected to the first electrode portion E14 of the fourth transistor T4 among the second semiconductor layers on the additional interlayer insulating layer 124 through a second connection hole CNH12.

The element layer 130 may be disposed on the circuit layer 120 and may include light emitting elements LE respectively corresponding to the light emitting areas EA.

Each of the light emitting elements LE may include an anode electrode 131 and a cathode electrode 134 that face each other, and a light emitting layer 133 disposed between the anode electrode 131 and the cathode electrode 134. Each of the light emitting elements LE may further include a first common layer 135 disposed between the anode electrode 131 and the light emitting layer 133, and a second common layer 136 disposed between the light emitting layer 133 and the cathode electrode 134.

For example, the element layer 130 may include anode electrodes 131 disposed in the light emitting areas EA, a pixel defining layer 132 disposed in the non-light emitting area NEA between the light emitting areas EA and covering an edge of the anode electrode 131, first common layers 135 disposed on the anode electrodes 131, light emitting layers 133 disposed on the first common layers 135, a second common layer 136 disposed on the light emitting layers 133 and the pixel defining layer 132, and a cathode electrode 134 disposed on the second common layer 136.

The anode electrode 131 may be disposed in each of the light emitting areas EA and electrically connected to one light emitting pixel driver EPD of the circuit layer 120. Such an anode electrode 131 may be referred to as a pixel electrode.

The anode electrode 131 may be electrically connected to the second anode connection electrode ANCE2 through a third anode contact hole ANCH3 penetrating through the second planarization layer 128.

The first common layer 135 may include an organic material with hole transport or hole injection properties.

The light emitting layer 133 may include an organic light emitting material that converts electron-hole pairs into light.

The second common layer 136 may include an organic material with electron transport or electron injection properties.

The cathode electrode 134 may be disposed entirely in the display area DA including the light emitting areas EA. The second power ELVSS may be commonly applied to the cathode electrode 134. Such a cathode electrode 134 may be referred to as a common electrode.

The sealing layer 140 may be disposed on the circuit layer 120 and cover the element layer 130.

As an example, the sealing layer 140 may include a first sealing layer 141 disposed on the element layer 130 and made of an inorganic insulating material, a second sealing layer 142 disposed on the first sealing layer 141, overlapping the element layer 130, and made of an organic insulating material, and a third sealing layer 143 disposed on the first sealing layer 141, covering the second sealing layer 142, and made of an inorganic insulating material.

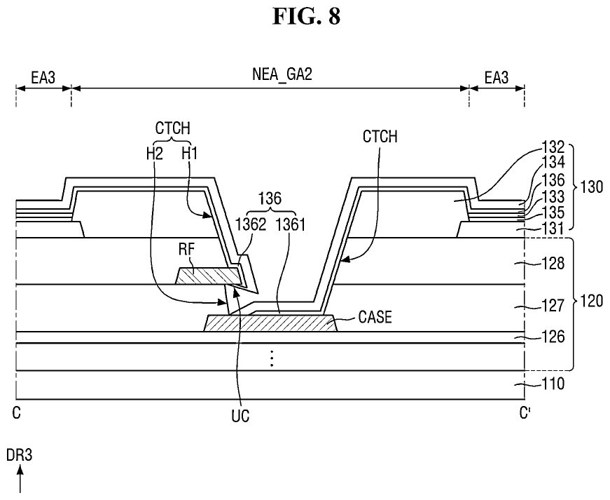

FIG. 7 is a schematic plan view illustrating a cathode auxiliary electrode in portion B of FIG. 2 according to embodiments. FIG. 8 is a schematic cross-sectional view taken along line C-C′ of FIG. 7 according to an embodiment.

Referring to FIG. 7, the circuit layer 120 of the display device 100 according to embodiments may include a cathode auxiliary electrode CASE disposed in a portion of the non-light emitting area between the light emitting areas EA.

A first spaced area GA1 having a first width may be disposed between two or more third light emitting areas EA31 and EA32, and EA33 and EA34 that are parallel in the second direction DR2 among the third light emitting areas EA3. A second spaced area GA2 having a second width greater than the first width may be disposed between the two or more third light emitting areas EA31 and EA32 and the other two or more third light emitting areas EA33 and EA34.

For example, the non-light emitting area may include the first spaced area GA1 disposed with the first width between the two or more third light emitting areas EA31 and EA32, and EA33 and EA34 that are parallel in the second direction DR2, and the second spaced area GA2 disposed between the two or more third light emitting areas EA31 and EA32 and the other two or more third light emitting areas EA33 and EA34.

The cathode auxiliary electrode CASE may be disposed in the second spaced area GA2 having a relatively wide second width.

The cathode auxiliary electrode CASE may be disposed in the display area DA and may be electrically connected to the second power line that transmits the second power (ELVSS in FIG. 5).

The second power line may be disposed as at least one of the first gate conductive layer on the first gate insulating layer (122 in FIG. 6), the second gate conductive layer on the second gate insulating layer (123 in FIG. 6), and the gate conductive layer on the third gate insulating layer (125 in FIG. 6).

In other embodiments, the second power line may be disposed on the same layer as the first light blocking portion (LB1 in FIG. 6) on the substrate (110 in FIG. 6).

Referring to FIG. 8, a portion of each of the roof portion RF overlapping a side of the cathode auxiliary electrode CASE and the cathode auxiliary electrode CASE may be exposed to the second common layer 136 through a cathode connection hole CTCH.

In an undercut structure UC by the roof portion RF, a gap may be formed where the second common layer 136 is separated.

For example, a portion of the second common layer 136 overlapping the cathode connection hole CTCH may include a first division portion 1361 disposed on the cathode auxiliary electrode CASE, and a second division portion 1362 in contact with the roof portion RF and spaced apart from the first division portion 1361.

In other words, the second common layer 136 may be divided into the first division portion 1361 and the second division portion 1362 by the undercut structure UC formed by the roof portion RF, and between the first division portion 1361 and the second division portion 1362, a gap may be formed through which the cathode auxiliary electrode CASE is exposed between the second common layers 136.

Accordingly, the cathode electrode 134 may be electrically connected to the cathode auxiliary electrode CASE by being in contact with the cathode auxiliary electrode CASE through the cathode connection hole CTCH and the gap of the second common layer 136.

The roof portion RF may overlap only a portion of an edge of the cathode auxiliary electrode CASE. In this way, the second common layer 136 (i.e., the first division portion 1361) and the cathode electrode 134 that overlap the cathode auxiliary electrode CASE may extend to the light emitting area EA through a portion of a side surface of the cathode connection hole CTCH where the roof portion RF does not protrude.

According to an embodiment, as illustrated in FIG. 8, the cathode auxiliary electrode CASE may be disposed as the first source drain conductive layer on the interlayer insulating layer 126.

The roof portion RF may be disposed as the second source drain conductive layer on the first planarization layer 127.

In this case, the cathode connection hole CTCH may include a first hole H1 penetrating through the pixel defining layer 132 and the second planarization layer 128, and a second hole H2 penetrating through the first planarization layer 127.

A portion of the second hole H2 may be disposed below the roof portion RF and may have a more concave shape than the roof portion RF. For example, as a portion of the roof portion RF protrudes more than the second hole H2, the undercut structure UC may be formed.

The gap in the second common layer 136 (i.e., between the first division portion 1361 and the second division portion 1362) may be formed in the undercut structure UC between the roof portion RF and the second hole H2.

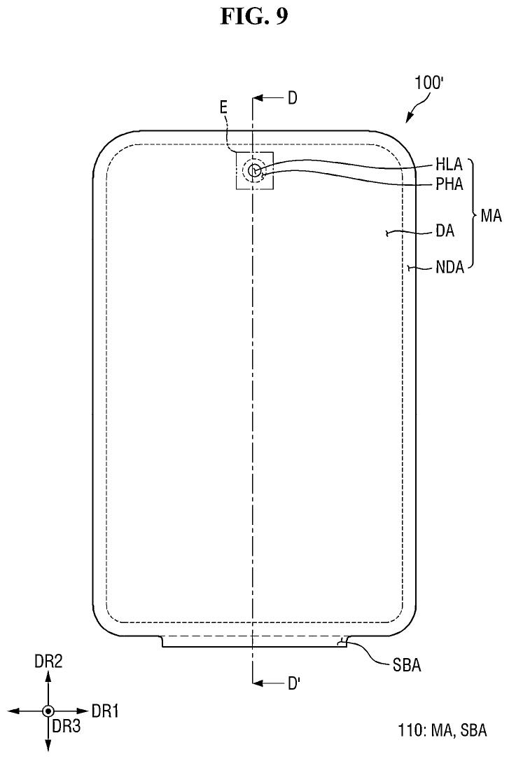

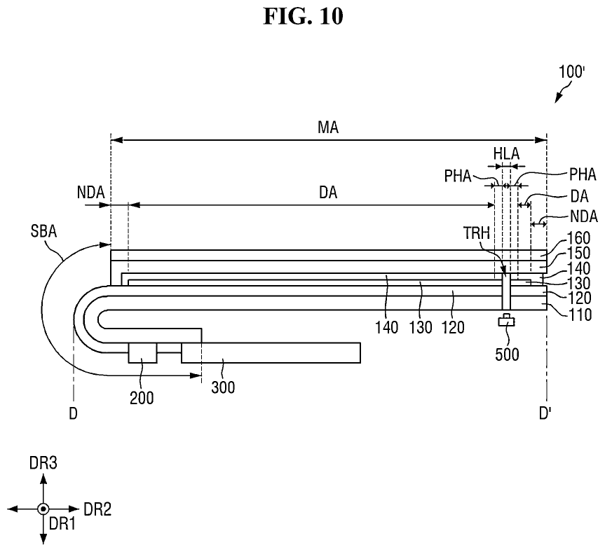

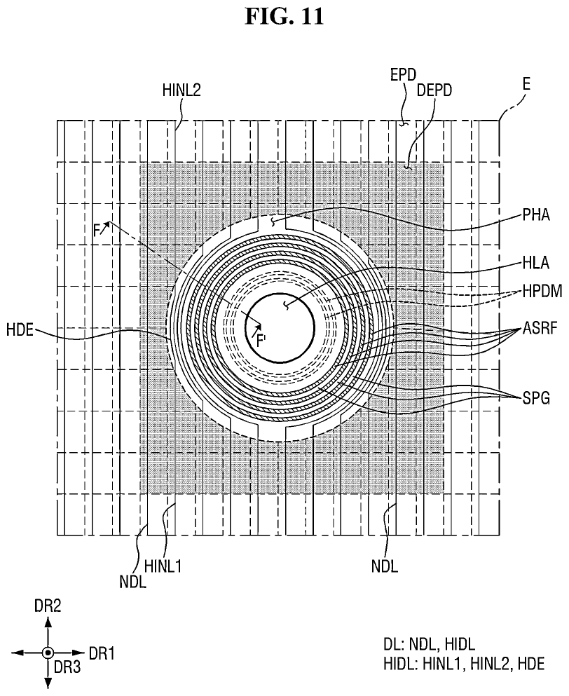

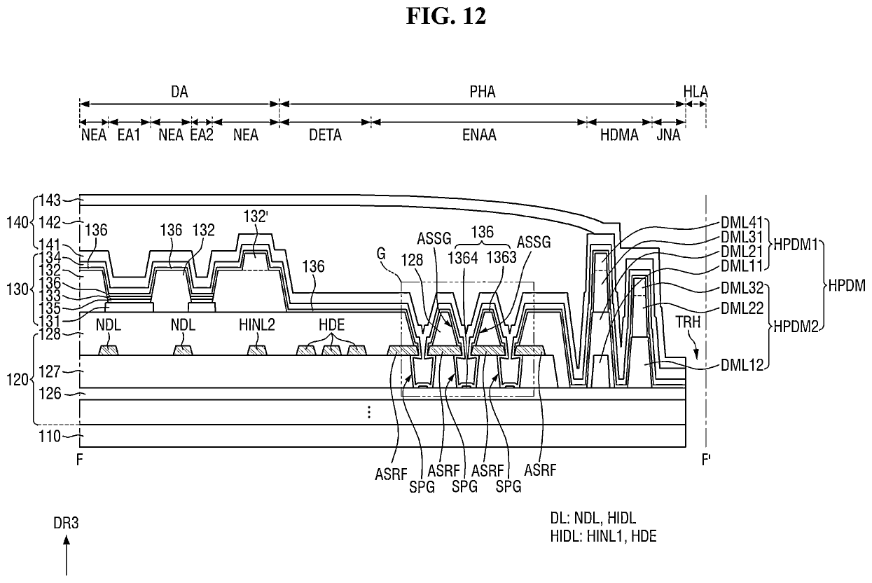

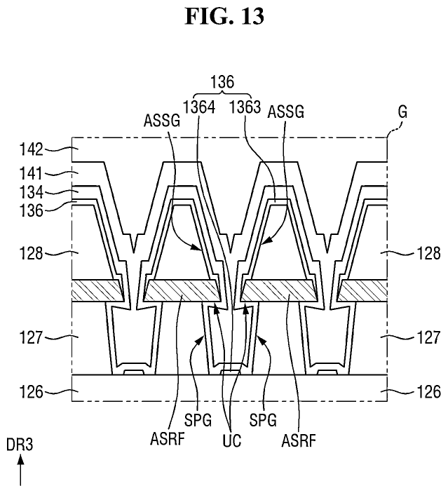

FIG. 9 is a schematic plan view illustrating a display device according to other embodiments. FIG. 10 is a schematic cross-sectional view taken along line D-D′ of FIG. 9. FIG. 11 is a schematic plan view illustrating portion E of FIG. 9. FIG. 12 is a schematic cross-sectional view taken along line F-F′ of FIG. 11 according to an embodiment of FIG. 8. FIG. 13 is an enlarged schematic view illustrating portion G of FIG. 12.

Referring to FIG. 9, a substrate 110 of a display device 100′ according to other embodiments may include a hole area HLA surrounded by the display area DA, and a hole peripheral area PHA disposed between the hole area HLA and the display area DA.

Referring to FIG. 10, the display device 100′ according to other embodiments may further include a light transmitting hole TRH formed in the hole area HLA.

The light transmitting hole TRH may form a light path for light sensing of an optical device 500 disposed below the hole area HLA of the display device 100′.

The light transmitting hole TRH may penetrate through the substrate 110, the circuit layer 120, the element layer 130, and the sealing layer 140.

Referring to FIG. 11, the circuit layer (120 in FIG. 12) of the display device 100′ according to other embodiments may include two or more auxiliary roof portions ASRF disposed in the hole peripheral area PHA and sequentially surrounding the hole area HLA, and one or more separation grooves SPG positioned between the two or more auxiliary roof portions ASRF.

As described above with reference to FIG. 6, as the second common layer (136 in FIG. 6) of the element layer (130 in FIG. 10) is disposed throughout the display area DA, the second common layer 136 may also be disposed in the hole peripheral area PHA surrounded by the display area DA.

Therefore, a permeation path for oxygen or moisture may be easily formed by the light transmitting hole TRH in the hole area HLA and the second common layer 136 in the hole peripheral area PHA.

To prevent such a problem, according to other embodiments, as two or more auxiliary roof portions ASRF and one or more separation grooves SPG are disposed in the hole peripheral area PHA, the second common layer 136 in the hole peripheral area PHA may be separated. In this way, the permeation of oxygen or moisture through the second common layer (136 in FIG. 6) in the hole peripheral area PHA may be delayed.

The display device 100′ according to other embodiments may further include one or more hole peripheral dams HPDM disposed between two or more auxiliary roof portions ASRF of the hole peripheral area PHA and the hole area HLA and surrounding the hole area HLA.

One or more hole peripheral dams HPDM may be a barrier that blocks the second sealing layer (142 in FIG. 6) of the sealing layer (140 in FIG. 10) including an organic material from diffusing into the hole area HLA.

The circuit layer (120 in FIG. 10) may include light emitting pixel drivers EPD arranged in the first direction DR1 and the second direction DR2 in the display area DA, and data lines DL that transmit the data signals (Vdata in FIG. 5) to the light emitting pixel drivers EPD and extend in the second direction DR2.

According to other embodiments, as the light emitting pixel drivers EPD are also arranged in the display area DA adjacent to the hole peripheral area PHA, the data lines DL may include hole intersecting data lines HIDL that intersect the hole area HLA or the hole peripheral area PHA.

For example, the data lines DL may include hole intersecting data lines HIDL that intersect the hole area HLA or the hole peripheral area PHA, and normal data lines NDL except for the hole intersecting data lines HIDL.

Each of the hole interesting data lines HIDL may include a first hole separation line HINL1 facing a side of the hole peripheral area PHA in the second direction DR2, a second hole separation line HINL2 facing another side of the hole peripheral area PHA in the second direction DR2, and a hole bypass line HDE disposed in the hole peripheral area PHA and electrically connecting between the first hole separation line HINL1 and the second hole separation line HINL2.

The hole bypass line HDE may be disposed between two or more auxiliary roof portions ASRF and the display area DA, and may be in the form of a curved arc extending parallel to a periphery of the two or more auxiliary roof portions ASRF.

Each of the normal data lines NDL may be provided in the form that does not intersect the hole area HLA and the hole peripheral area PHA and does not include a curved hole bypass line HDE disposed in the hole peripheral area PHA.

According to other embodiments, the circuit layer 120 may further include dummy light emitting pixel drivers DEPD disposed closest to the hole peripheral area PHA.

The dummy light emitting pixel drivers DEPD may have the same structure as the light emitting pixel drivers EPD, except that they are not electrically connected to the light emitting elements (LE in FIG. 5) of the element layer (130 in FIG. 10).

As the dummy light emitting pixel drivers DEPD surrounding the hole peripheral area PHA are arranged, physical or chemical shock generated in a process of disposing the light transmitting hole (TRH in FIG. 10) in the hole area HLA may be buffered by the dummy light emitting pixel drivers DEPD. Therefore, the possibility of damage to the light emitting pixel drivers EPD during the process of disposing the light transmitting hole (TRH in FIG. 10) may be reduced.

As illustrated in FIG. 12, according to other embodiments, two or more auxiliary roof portions ASRF and one or more separation grooves SPG may be disposed in a scaling auxiliary area ENAA of the hole peripheral area PHA spaced apart from each of the hole area HLA and display area DA.

Like the roof portion of the display area DA (RF in FIG. 8), the auxiliary roof portions ASRF of the hole peripheral area PHA may also be disposed as the second source drain conductive layer on the first planarization layer 127.

Like the second hole (H2 in FIG. 8) of the cathode connection hole (CTCH in FIG. 8) of the display area DA, each of the one or more separation grooves SPG may penetrate through the first planarization layer 127.

In this way, the roof portion (RF in FIG. 8) and the cathode connection hole (CTCH in FIG. 8) of the display area DA may be provided together with the auxiliary roof portions ASRF and the separation groove SPG of the hole peripheral area PHA. As a result, since a separate mask process and etching process for disposing the roof portion (RF in FIG. 8) and the cathode connection hole (CTCH in FIG. 8) of the display area DA may be omitted, the time and cost required to manufacture the display device 100′ including the roof portion (RF in FIG. 8) and the cathode connection hole (CTCH in FIG. 8) may be reduced.

As illustrated in FIG. 13, in a direction in which the two or more auxiliary roof portions ASRF face each other (i.e., a direction between the hole area HLA and the display area DA), at least a portion of an edge of each of the two or more auxiliary roof portions ASRF may protrude more than the one or more separation grooves SPG.

For example, in the direction in which the two or more auxiliary roof portions ASRF face each other, a width of a spaced area between the auxiliary roof portions ASRF may be smaller than a width of the one or more separation grooves SPG.

As a result, in the spaced area between the two or more auxiliary roof portions ASRF, an undercut structure UC in which the edges of two or more auxiliary roof portions ASRF protrude more than the one or more separation grooves SPG may be formed.

Since the second common layer 136 and the cathode electrode 134 of the element layer 130 are entirely disposed in the display area DA, the second common layer 136 and the cathode electrode 134 may also be disposed in the hole peripheral area PHA surrounded by the display area DA.

The second common layer 136 may be disposed on the light emitting layers 133, the pixel defining layer 132, and the spacer layer 132′ in the display area DA.

In case that the second planarization layer 128 extends to the hole peripheral area PHA and covers two or more auxiliary roof portions ASRF, the circuit layer 120 may further include an auxiliary separation groove ASSG that overlaps the one or more separation grooves SPG and penetrates through the second planarization layer 128.

The pixel defining layer 132 may be disposed in the display area DA and may not extend to the hole peripheral area PHA. Accordingly, the second common layer 136 may be disposed on the second planarization layer 128 in the hole peripheral area PHA.

In other embodiments, the second planarization layer 128 may not extend to the hole peripheral area PHA. In this case, the second common layer 136 may be disposed on two or more auxiliary roof portions ASRF in the sealing auxiliary area ENAA of the hole peripheral area PHA.

As one or more separation grooves SPG are disposed with a width greater than a gap between the two or more auxiliary roof portions ASRF, an undercut structure UC may be formed between the two or more auxiliary roof portions ASRF and the one or more separation grooves SPG.

Accordingly, in the process of disposing the second common layer 136, an organic material of the second common layer 136 may be difficult to connect from a side surface of the auxiliary roof portions ASRF to a side surface of the separation groove SPG due to the auxiliary roof portions ASRF protruding more than the separation groove SPG. For example, a portion of the second common layer 136 disposed in the hole peripheral area PHA may be separated by the undercut structure UC.

In other words, a portion of the second common layer 136 disposed in the hole peripheral area PHA may include two or more third division portions 1363 overlapping the two or more auxiliary roof portions ASRF, and one or more fourth division portions 1364 disposed in the one or more separation grooves SPG and spaced apart from the two or more third division portions 1363.

The data lines DL may be disposed on the second source drain conductive layer on the first planarization layer 127.

The data lines DL may include hole intersecting data lines HIDL and normal data lines NDL. The hole intersecting data line HIDL may include a first hole separation line HINL1, a second hole separation line (HINL2 in FIG. 11), and a hole bypass line HDE.

The hole bypass lines HDE of the hole intersecting data lines HIDL may be disposed in a bypass area DETA in the hole peripheral area PHA between the display area DA and the sealing auxiliary area ENAA.

According to other embodiments, the display device 100′ may include one or more hole peripheral dams HPDM disposed between two or more auxiliary roof portions ASRF of the hole peripheral area PHA and the hole area HLA and surrounding the hole area HLA.

For example, one or more hole peripheral dams HPDM may be sequentially disposed in the hole peripheral dam area HDMA in the hole peripheral area PHA between the sealing auxiliary area ENAA and the hole area HLA.

Each of the one or more hole peripheral dams HPDM may include two or more dam layers.

Each of the two or more dam layers may be disposed on the same layer as one of the first planarization layer 127, the second planarization layer 128, the pixel defining layer 132, and the spacer layer 132′.

As an example, one or more hole peripheral dams HPDM may include a first hole peripheral dam HPDM1 adjacent to the sealing auxiliary area ENAA, and a second hole peripheral dam HPDM2 disposed between the first hole peripheral dam HPDM1 and the hole area HLA.

The first hole peripheral dam HPDM1 may include a first dam layer DML11 on the same layer as the first planarization layer 127, a second dam layer DML21 on the same layer as the second planarization layer 128, a third dam layer DML31 on the same layer as the pixel defining layer 132, and a fourth dam layer DML41 on the same layer as the spacer layer 132′.

The second hole peripheral dam HPDM2 may include a first dam layer DML12 on the same layer as the second planarization layer 128, a second dam layer DML22 on the same layer as the pixel defining layer 132, and a third dam layer DML32 on the same layer as the spacer layer 132′.

The sealing layer 140 may include a first sealing layer 141 disposed on the element layer 130, a second sealing layer 142 disposed on the first sealing layer 141 and overlapping the display area DA, and a third sealing layer 143 disposed on the first sealing layer 141 and covering the second sealing layer 142.

The second sealing layer 142 may extend to one or more hole peripheral dams HPDM and include an organic insulating material spaced apart from the hole area HLA.

Each of the first sealing layer 141 and the third sealing layer 143 may include an inorganic insulating material.

Since the second sealing layer 142 extends to the one or more hole peripheral dams HPDM, the first sealing layer 141 and the third sealing layer 143 may be in contact with each other in a junction area JNA between the hole area HLA and one or more hole peripheral dams HPDM of the hole peripheral area PHA.

The circuit layer 120 may include a buffer layer (121 in FIG. 6) disposed on the substrate 110, a first gate insulating layer (122 in FIG. 6) disposed on the buffer layer 121, a second gate insulating layer (123 in FIG. 6) disposed on the first gate insulating layer 122, an additional interlayer insulating layer (124 in FIG. 6) disposed on the second gate insulating layer (123 in FIG. 6), and a third gate insulating layer (125 in FIG. 6) disposed on the additional interlayer insulating layer (124 in FIG. 6). An interlayer insulating layer 126 may be disposed on the third gate insulating layer 125.

Each of the buffer layer 121, the first gate insulating layer 122, the second gate insulating layer 123, the additional interlayer insulating layer 124, the third gate insulating layer 125, and the interlayer insulating layer 126 may include an inorganic insulating material.

Each of the second common layer 136 and the cathode electrode 134 may be entirely disposed in the display area DA.

Each of the first sealing layer 141 and the third sealing layer 143 may include an inorganic insulating material and may be entirely disposed in the display area DA.

Accordingly, the light transmitting hole TRH of the hole area HLA may penetrate through the third sealing layer 143, the first sealing layer 141, the cathode electrode 134, the second common layer 136, the interlayer insulating layer 126, the third gate insulating layer 125, the additional interlayer insulating layer 124, the second gate insulating layer 123, the first gate insulating layer 122, the buffer layer 121, and the substrate 110.

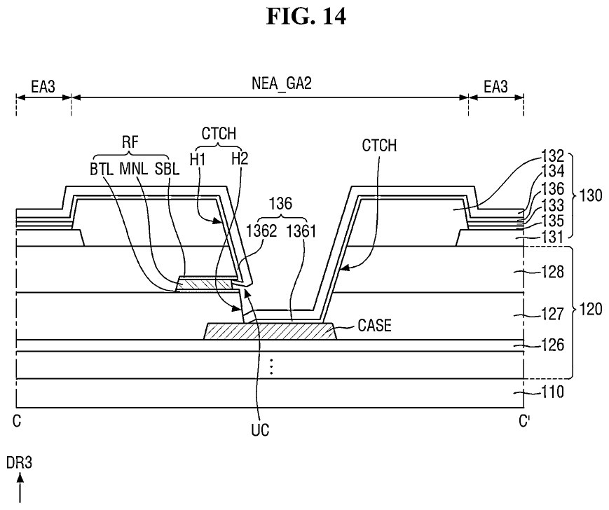

FIG. 14 is a schematic cross-sectional view taken along line C-C′ of FIG. 7 according to an embodiment.

Since a display device 100 according to an embodiment illustrated in FIG. 14 may be substantially the same as the display device according to the embodiments of FIGS. 7 and 8, except that the undercut structure UC that induces the gap in the second common layer 136 is formed between a sub-conductive layer SBL and a main conductive layer MNL of the roof portion RF, redundant descriptions will be omitted below.

As illustrated in FIG. 14, the second source drain conductive layer on the first planarization layer 127 may include a main conductive layer MNL and a sub-conductive layer SBL disposed on the main conductive layer MNL and including a metal material different from the main conductive layer MNL.

The main conductive layer MNL may include a low-resistance metal material such as aluminum (Al), copper (Cu), or silver (Ag).

The sub-conductive layer SBL may include a metal material that may block the metal material of the main conductive layer MNL from diffusing into the organic insulating material of the second planarization layer 128, and have a higher etch rate than the main conductive layer MNL. As an example, the sub-conductive layer SBL may include titanium (Ti).

The second source drain conductive layer may further include a bottom layer BTL disposed below the main conductive layer MNL.

The bottom layer BTL may include a metal material that may block the metal material of the main conductive layer MNL from diffusing into the organic insulating material of the first planarization layer 127, and have a higher etch rate than the main conductive layer MNL. As an example, the bottom layer BTL may include titanium (Ti).

In this case, the cathode connection hole CTCH may include a first hole H1 penetrating through the pixel defining layer 132 and the second planarization layer 128, and a second hole H2 penetrating through the first planarization layer 127.

The cathode connection hole CTCH may expose an edge of the roof portion RF.

For example, the first hole H1 may be in contact with a side surface of the sub-conductive layer SBL, and the second hole H2 may be in contact with a side surface of the bottom layer BTL.

One side of the roof portion RF exposed through the cathode connection hole CTCH may include an undercut structure UC as the sub-conductive layer SBL protrudes more than the main conductive layer MNL.

The gap in the second common layer 136 (i.e., between the first division portion 1361 and the second division portion 1362) may be formed in the undercut structure UC of the roof portion RF.

For example, the second division portion 1362 extending along the first hole H1 may not extend to the side surface of the main conductive layer MNL, which is concave compared to the side surface of the sub-conductive layer SBL, but may be disposed only up to the side surface of the sub-conductive layer SBL.

As an example, the undercut structure UC of the roof portion RF may be formed by forming a hole that penetrates through the second planarization layer 128 and exposes a side of the roof portion RF, and partially removing the main conductive layer MNL on a side of the roof portion RF using an etching material for disposing the anode electrodes 131, before the process of disposing the anode electrodes 131.

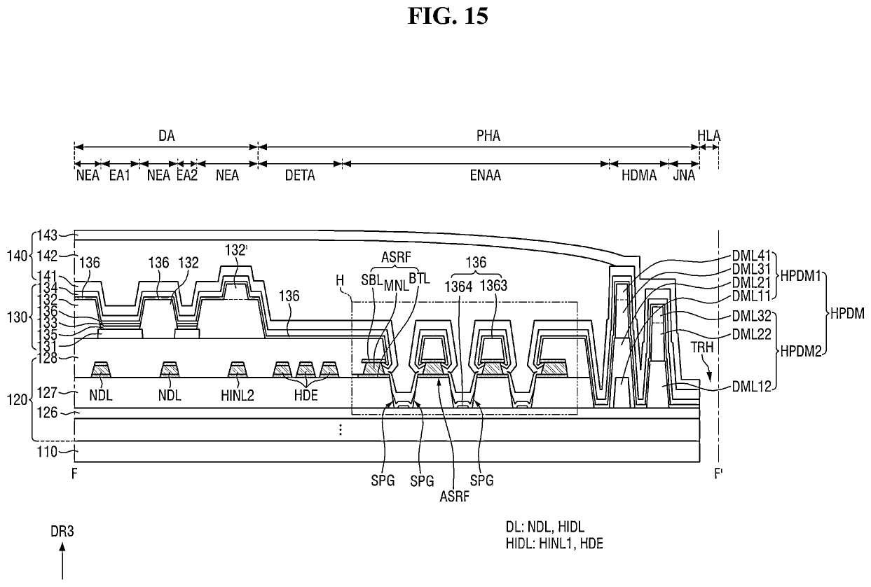

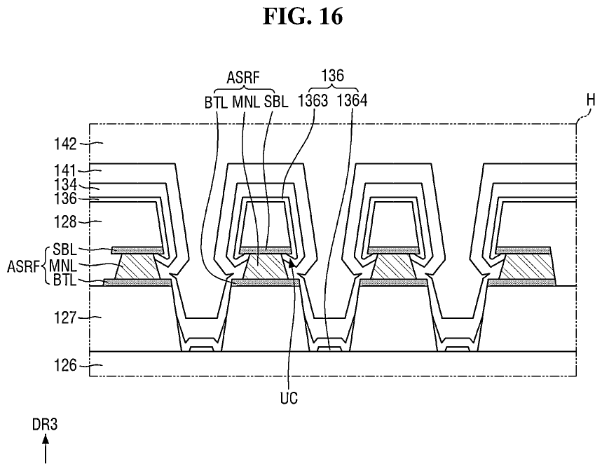

FIG. 15 is a schematic cross-sectional view taken along line F-F′ of FIG. 11 according to an embodiment of FIG. 14. FIG. 16 is an enlarged schematic view illustrating portion H of FIG. 15.

Since a display device 100′ according to another embodiment illustrated in FIGS. 15 and 16 may be substantially the same the display device according to other embodiments illustrated in FIGS. 9, 10, 11, 12, and 13, except that a portion of the edge of each of the two or more auxiliary roof portions ASRF exposed through one or more separation grooves SPG includes an undercut structure UC in which the sub-conductive layer SBL protrudes more than the main conductive layer MNL, and a portion of the second common layer 136 disposed in the hole peripheral area PHA is separated from the undercut structure UC of the two or more auxiliary roof portions ASRF, redundant descriptions will be omitted below.

According to another embodiment of FIGS. 15 and 16, two or more auxiliary roof portions ASRF and one or more separation grooves SPG disposed in the hole peripheral area PHA may be formed together with a roof portion (RF in FIG. 14) and a cathode connection hole (CTCH in FIG. 14) disposed in the display area DA. As a result, the time and cost required to manufacture the display device 100′ may be reduced.

According to another embodiment of FIGS. 15 and 16, a portion of the second common layer 136 disposed in the hole peripheral area PHA may include two or more third division portions 1363 extending to the sub-conductive layer SBL of the two or more auxiliary roof portions ASRF, and one or more fourth division portions 1364 disposed in the one or more separation grooves SPG and spaced apart from the two or more third division portions 1363.

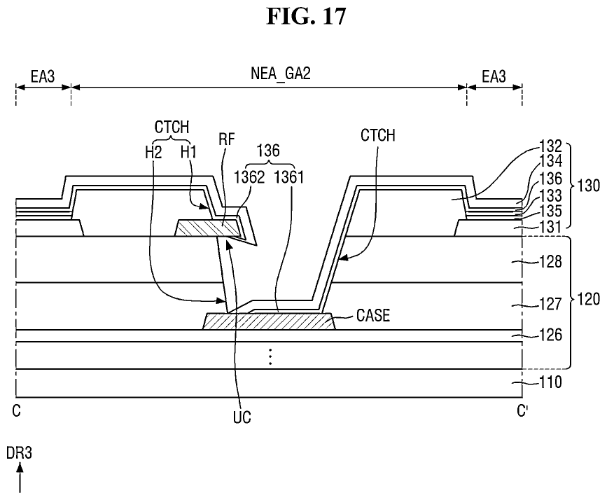

FIGS. 17, 18, 19, and 20 are each schematic cross-sectional views taken along line C-C′ of FIG. 7 according to an embodiment.

Since a display device 100 according to an embodiment illustrated in FIG. 17 may be substantially the same as the display device according to the embodiments of FIGS. 7 and 8, except that the roof portion RF is disposed on the second planarization layer 128 in the same layer as the anode electrodes 131, the first hole H1 of the cathode connection hole CTCH penetrates through the pixel defining layer 132, and the second hole H2 of the cathode connection hole CTCH penetrates through the second planarization layer 128 and the first planarization layer 127, redundant descriptions will be omitted below.

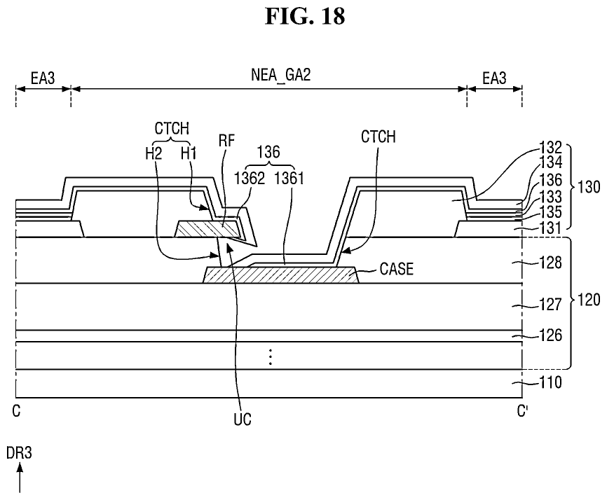

Since a display device 100 according to an embodiment illustrated in FIG. 18 may be substantially the same as the display device according to the embodiment of FIG. 17 except that the cathode auxiliary electrode CASE is disposed as the second source drain conductive layer on the first planarization layer 127, redundant descriptions will be omitted below.

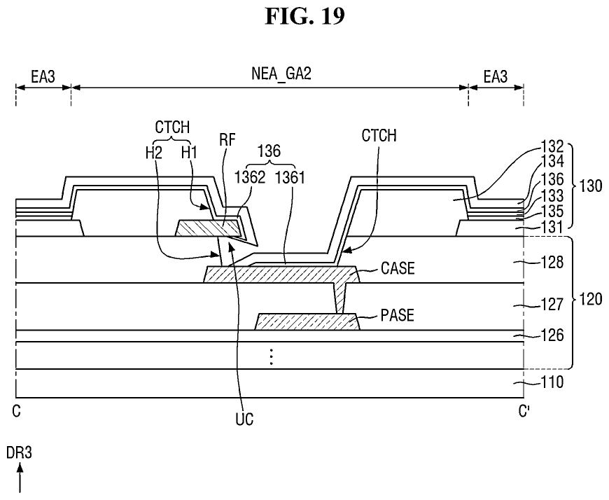

Since a display device 100 according to an embodiment illustrated in FIG. 19 may be substantially the same as the display device according to the embodiment of FIG. 18 except that the circuit layer 120 further includes a power auxiliary electrode PASE disposed as the first source drain conductive layer on the interlayer insulating layer 126, and the cathode auxiliary electrode CASE is electrically connected to the power auxiliary electrode PASE through a hole penetrating through the first planarization layer 127, redundant descriptions will be omitted below.

The cathode auxiliary electrode CASE may be electrically connected to the second power line that transmits the second power (ELVSS in FIG. 5). As an example, the cathode auxiliary electrode CASE may be a portion of the second power line.

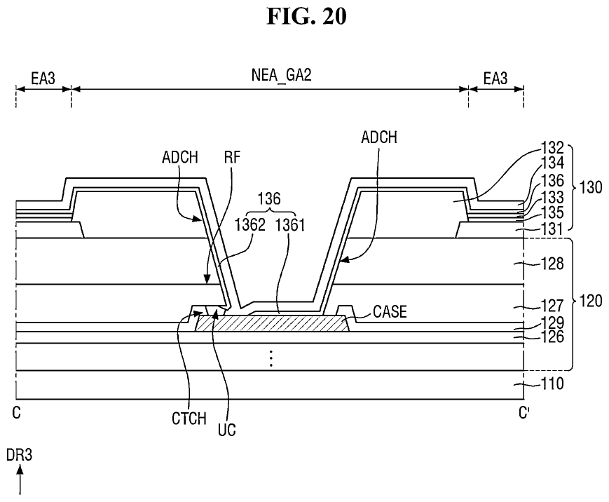

Since a display device 100 according to an embodiment illustrated in FIG. 20 is substantially the same as the display device according to the embodiments of FIGS. 7 and 8 except that the circuit layer 120 further includes an auxiliary insulating layer 129 disposed on the interlayer insulating layer 126 and covering the first source drain conductive layer including the cathode auxiliary electrode CASE, and an additional connection hole ADCH penetrating through the pixel defining layer 132, the second planarization layer 128, and the first planarization layer 127, the cathode connection hole CTCH is connected to the additional connection hole ADCH and penetrates through the auxiliary insulating layer 129, and the roof portion RF is disposed around the additional connection hole ADCH and is a portion of the first planarization layer 127 that protrudes more than the auxiliary insulating layer 129, redundant descriptions will be omitted below.

The roof portion RF formed as a portion of the first planarization layer 127 may protrude more than the auxiliary insulating layer 129 by the cathode connection hole CTCH.

For example, the auxiliary insulating layer 129 may cover an edge of the cathode auxiliary electrode CASE. A portion of the auxiliary insulating layer 129 overlapping a side of the cathode auxiliary electrode CASE may be covered with the first planarization layer 127, and another portion of the auxiliary insulating layer 129 overlapping another side of the cathode auxiliary electrode CASE may be more concave than a portion of the first planarization layer 127 (i.e., the roof portion RF).

For example, as the roof portion RF protrudes more than the auxiliary insulating layer 129, the undercut structure UC may be formed.

A gap in the second common layer 136 may be formed in the undercut structure UC between the roof portion RF and the auxiliary insulating layer 129.

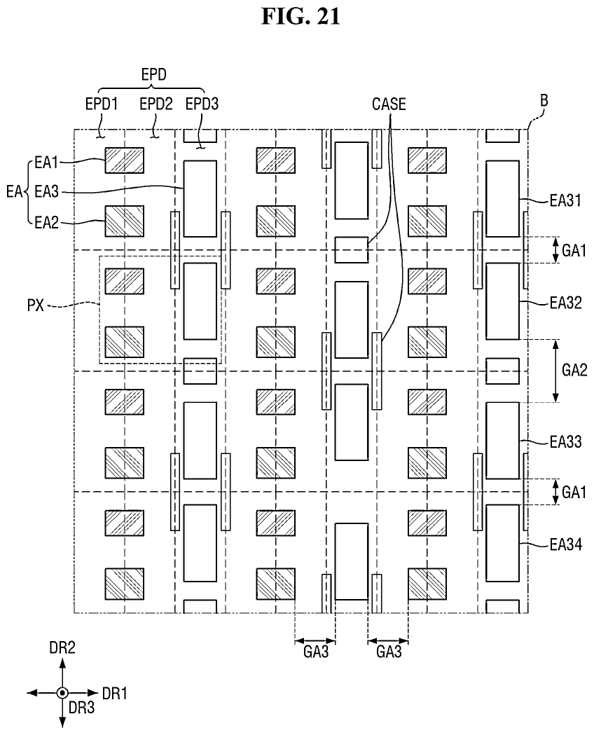

FIG. 21 is a schematic plan view illustrating a cathode auxiliary electrode in portion B of FIG. 2 according to an embodiment.

Since a display device 100 according to an embodiment illustrated in FIG. 21 may be substantially the same as the display device according to the embodiments of FIGS. 7 to 20 except that the cathode auxiliary electrode CASE is adjacent to a side of two or more third light emitting areas EA in the second direction DR2, and is also adjacent to a side of the third light emitting areas EA in the first direction DR1, redundant descriptions will be omitted below.

As illustrated in FIG. 21, in case that a width of the third light emitting areas EA decreases in the first direction DR1, a third spaced area GA3 disposed on a side of the third light emitting areas EA3 may be disposed with a greater width than a third spaced area GA3′ in FIG. 7.

As the third spaced area GA3 is provided with a sufficiently great width, the cathode auxiliary electrode CASE may be disposed not only in the first spaced area GA1 but also in the third spaced area GA3.

The cathode auxiliary electrode CASE in the third spaced area GA3 may be adjacent to the first spaced area GA1 and a portion of each of two or more third light emitting areas EA31 and EA32, and EA33 and EA34 parallel to each other in the second direction DR2 and spaced apart by the first spaced area GA1.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A display device, comprising:
a substrate including a display area in which light emitting areas are disposed;
a circuit layer disposed on the substrate; and
an element layer disposed on the circuit layer, wherein
the circuit layer includes a cathode auxiliary electrode disposed in a portion of a non-light emitting area between the light emitting areas in the display area,
the element layer includes:
anode electrodes disposed in the light emitting areas;
a pixel defining layer disposed in the non-light emitting area and overlapping an edge of each of the anode electrodes;
first common layers disposed on the anode electrodes;
light emitting layers disposed on the first common layers;
a second common layer disposed on the pixel defining layer and the light emitting layers; and
a cathode electrode disposed on the second common layer,
a portion of each of a roof portion overlapping a side of the cathode auxiliary electrode and the cathode auxiliary electrode is exposed to the second common layer through a cathode connection hole,
in an undercut structure formed by the roof portion, a gap is formed in which the second common layer is separated, and
the cathode electrode is electrically connected to the cathode auxiliary electrode through the cathode connection hole and the gap in the second common layer.

2. The display device of claim 1, wherein
the light emitting areas include:
first light emitting areas emitting light of a first color;
second light emitting areas emitting light of a second color having a lower wavelength band than the first color; and
third light emitting areas emitting light of a third color having a lower wavelength band than the second color,
the first light emitting areas are parallel to each other in a first direction,
the second light emitting areas are parallel to each other in the first direction,
each of the third light emitting areas is adjacent to a portion of each of the first light emitting areas and a portion of each of the second light emitting areas in the first direction,
in a second direction intersecting the first direction, the first light emitting areas and the second light emitting areas are alternately disposed,
the third light emitting areas are parallel to each other in the second direction, and
a first spaced area having a first width is disposed between two or more third light emitting areas that are parallel in the second direction among the third light emitting areas, and a second spaced area having a second width greater than the first width is disposed between the two or more third light emitting areas and the other two or more third light emitting areas.

3. The display device of claim 2, wherein the cathode auxiliary electrode is disposed in the second spaced area.

4. The display device of claim 2, wherein
in the first direction, a third spaced area is disposed on a side of the two or more third light emitting areas, and
the cathode auxiliary electrode is disposed in the first spaced area and the third spaced area.

5. The display device of claim 2, wherein the circuit layer includes:
an interlayer insulating layer disposed on the substrate;
a first source drain conductive layer disposed on the interlayer insulating layer;
a first planarization layer overlapping the first source drain conductive layer;
a second source drain conductive layer disposed on the first planarization layer; and
a second planarization layer overlapping the second source drain conductive layer.

6. The display device of claim 5, wherein
the cathode auxiliary electrode is disposed as the first source drain conductive layer,
the roof portion is disposed as the second source drain conductive layer,
the cathode connection hole includes:
a first hole penetrating through the pixel defining layer and the second planarization layer; and
a second hole penetrating through the first planarization layer,
a portion of the roof portion protrudes more than the second hole, and
the gap in the second common layer is formed in an undercut structure between the roof portion and the second hole.

7. The display device of claim 6, wherein
the substrate further includes:
a hole area surrounded by the display area; and
a hole peripheral area disposed between the hole area and the display area,
the circuit layer further includes:
two or more auxiliary roof portions disposed as the second source drain conductive layer in the hole peripheral area on the first planarization layer and sequentially surrounding the hole area; and
one or more separation grooves positioned between the two or more auxiliary roof portions and penetrating through the first planarization layer,
a portion of an edge of each of the two or more auxiliary roof portions protrudes more than the one or more separation grooves, and
a portion of the second common layer disposed in the hole peripheral area is separated from an undercut structure formed between the two or more auxiliary roof portions and the one or more separation grooves.

8. The display device of claim 5, wherein
the second source drain conductive layer includes:
a main conductive layer; and
a sub-conductive layer disposed on the main conductive layer and including a metal material different from the main conductive layer,
the cathode auxiliary electrode is disposed as the first source drain conductive layer,
the roof portion is disposed as the second source drain conductive layer,
the cathode connection hole includes:
a first hole penetrating through the pixel defining layer and the second planarization layer; and
a second hole penetrating through the first planarization layer,
a portion of the roof portion exposed through the cathode connection hole includes an undercut structure in which the sub-conductive layer protrudes more than the main conductive layer, and
the gap in the second common layer is formed in the undercut structure of a portion of the roof portion.

9. The display device of claim 8, wherein
the substrate further includes:
a hole area surrounded by the display area; and
a hole peripheral area disposed between the hole area and the display area, the circuit layer further includes:
two or more auxiliary roof portions disposed as the second source drain conductive layer in the hole peripheral area on the first planarization layer and sequentially surrounding the hole area; and
one or more separation grooves positioned between the two or more auxiliary roof portions and penetrating through the first planarization layer,
a portion of an edge of each of the two or more auxiliary roof portions exposed through the one or more separation grooves includes an undercut structure in which the sub-conductive layer protrudes more than the main conductive layer, and
a portion of the second common layer disposed in the hole peripheral area is separated from the undercut structure of the two or more auxiliary roof portions.

10. The display device of claim 5, wherein
the cathode auxiliary electrode is disposed as the first source drain conductive layer,
the roof portion is disposed on the second planarization layer in the same layer as the anode electrodes,
the cathode connection hole includes a first hole penetrating through the pixel defining layer, and a second hole penetrating through the second planarization layer and the first planarization layer,
a portion of the roof portion protrudes more than the second hole, and
the gap in the second common layer is formed in an undercut structure between the roof portion and the second hole.

11. The display device of claim 5, wherein
the cathode auxiliary electrode is disposed as the second source drain conductive layer,
the roof portion is disposed on the second planarization layer in the same layer as the anode electrodes,
the cathode connection hole includes:
a first hole penetrating through the pixel defining layer; and
a second hole penetrating through the second planarization layer,
a portion of the roof portion protrudes more than the second hole, and
the gap in the second common layer is formed in an undercut structure between the roof portion and the second hole.

12. The display device of claim 11, wherein the circuit layer further includes a power auxiliary electrode disposed as the first source drain conductive layer and electrically connected to the cathode auxiliary electrode.

13. The display device of claim 5, wherein
the circuit layer further includes an auxiliary insulating layer disposed on the interlayer insulating layer and overlapping the first source drain conductive layer,
each of the interlayer insulating layer and the auxiliary insulating layer includes an inorganic insulating material,
each of the first planarization layer, the second planarization layer, and the pixel defining layer includes an organic insulating material,
the cathode auxiliary electrode is disposed as the first source drain conductive layer,
the cathode connection hole is extended to an additional connection hole penetrating through the pixel defining layer, the second planarization layer, and the first planarization layer, and penetrates through the auxiliary insulating layer,
the roof portion is a portion of the first planarization layer disposed around the additional connection hole and protruding more than the auxiliary insulating layer, and
the gap in the second common layer is formed in an undercut structure between the roof portion and the auxiliary insulating layer.

14. A display device, comprising:
a substrate including a display area in which light emitting areas are disposed;
a circuit layer disposed on the substrate; and
an element layer disposed on the circuit layer, wherein
the circuit layer includes:
an interlayer insulating layer disposed on the substrate;
a first source drain conductive layer disposed on the interlayer insulating layer;
a first planarization layer overlapping the first source drain conductive layer;
a second source drain conductive layer disposed on the first planarization layer;
a second planarization layer overlapping the second source drain conductive layer; and
a cathode auxiliary electrode disposed as one of the first source drain conductive layer and the second source drain conductive layer in a portion of a non-light emitting area between the light emitting areas of the display area,
the element layer includes:
anode electrodes disposed in the light emitting areas;
a pixel definition layer disposed in the non-light emitting area and overlapping an edge of each of the anode electrodes;
first common layers disposed on the anode electrodes;
light emitting layers disposed on the first common layers;
a second common layer disposed on the pixel defining layer and the light emitting layers; and
a cathode electrode disposed on the second common layer,
a portion of each of a roof portion overlapping a side of the cathode auxiliary electrode and the cathode auxiliary electrode is exposed to the second common layer through a cathode connection hole,
in an undercut structure formed by the roof portion, a gap is formed in which the second common layer is separated, and
the cathode electrode is electrically connected to the cathode auxiliary electrode through the cathode connection hole and the gap of the second common layer.

15. The display device of claim 14, wherein
the cathode auxiliary electrode is disposed as the first source drain conductive layer,
the roof portion is disposed as the second source drain conductive layer,
the cathode connection hole includes a first hole penetrating through the pixel defining layer and the second planarization layer, and a second hole penetrating through the first planarization layer,
a portion of the roof portion protrudes more than the second hole, and
the gap in the second common layer is formed in an undercut structure between the roof portion and the second hole.

16. The display device of claim 15, wherein
the substrate further includes:
a hole area surrounded by the display area; and
a hole peripheral area disposed between the hole area and the display area, the circuit layer further includes:
two or more auxiliary roof portions disposed as the second source drain conductive layer in the hole peripheral area on the first planarization layer and sequentially surrounding the hole area; and
one or more separation grooves positioned between the two or more auxiliary roof portions and penetrating through the first planarization layer,
a portion of an edge of each of the two or more auxiliary roof portions protrudes more than the one or more separation grooves, and
a portion of the second common layer disposed in the hole peripheral area is separated from an undercut structure formed between the two or more auxiliary roof portions and the one or more separation grooves.

17. The display device of claim 14, wherein
the second source drain conductive layer includes a main conductive layer; and a sub-conductive layer disposed on the main conductive layer and including a metal material different from the main conductive layer,
the cathode auxiliary electrode is disposed as the first source drain conductive layer,
the roof portion is disposed as the second source drain conductive layer,
the cathode connection hole includes a first hole penetrating through the pixel defining layer and the second planarization layer, and a second hole penetrating through the first planarization layer,
a portion of the roof portion exposed through the cathode connection hole includes an undercut structure in which the sub-conductive layer protrudes more than the main conductive layer, and
the gap in the second common layer is formed in the undercut structure of a portion of the roof portion.

18. The display device of claim 17, wherein
the substrate further includes
a hole area surrounded by the display area; and
a hole peripheral area disposed between the hole area and the display area,
the circuit layer further includes:
two or more auxiliary roof portions disposed as the second source drain conductive layer in the hole peripheral area on the first planarization layer and sequentially surrounding the hole area; and
one or more separation grooves positioned between the two or more auxiliary roof portions and penetrating through the first planarization layer,
a portion of an edge of each of the two or more auxiliary roof portions exposed through the one or more separation grooves includes an undercut structure in which the sub-conductive layer protrudes more than the main conductive layer, and
a portion of the second common layer disposed in the hole peripheral area is separated from the undercut structure of the two or more auxiliary roof portions.

19. The display device of claim 14, wherein
the light emitting areas include:
first light emitting areas emitting light of a first color;
second light emitting areas emitting light of a second color having a lower wavelength band than the first color; and
third light emitting areas emitting light of a third color having a lower wavelength band than the second color,
the first light emitting areas are parallel to each other in a first direction,
the second light emitting areas are parallel to each other in the first direction,
each of the third light emitting areas is adjacent to a portion of each of the first light emitting areas and a portion of each of the second light emitting areas in the first direction,
in a second direction intersecting the first direction, the first light emitting areas and the second light emitting areas are alternately disposed,
the third light emitting areas are parallel to each other in the second direction,
a first spaced area having a first width is disposed between two or more third light emitting areas that are parallel in the second direction among the third light emitting areas, and a second spaced area having a second width greater than the first width is disposed between the two or more third light emitting areas and the other two or more third light emitting areas, and
the cathode auxiliary electrode is disposed in the second spaced area.

20. The display device of claim 19, wherein
in the first direction, a third spaced area is disposed on a side of the two or more third light emitting areas, and
the cathode auxiliary electrode is further disposed in the third spaced area.
